(19) United States
(12) Patent Application Publication
(10) Pub. No.: US 2025/0255164 A1
(43) Pub. Date: Aug. 7, 2025

(54) DISPLAY DEVICE, METHOD OF MANUFACTURING THE DISPLAY DEVICE, AND ELECTRONIC DEVICE INCLUDING THE DISPLAY DEVICE

(71) Applicant: Samsung Display Co., LTD., Yongin-si (KR)

(72) Inventors: NAKCHO CHOI, Yongin-si (KR); BEOMYEOL PARK, Yongin-si (KR)

(73) Assignee: Samsung Display Co., LTD., Yongin-si (KR)

(21) Appl. No.: 19/009,485

(22) Filed: Jan. 3, 2025

(30) Foreign Application Priority Data
Feb. 2, 2024 (KR) 10-2024-0016583

(51) Int. Cl. H10K 59/80; H10K 59/12

(52) U.S. Cl. CPC H10K 59/8792; H10K 59/1201; H10K 59/879

(57) ABSTRACT

A display device includes: a light emitting element disposed in a pixel area, first black matrix pattern layers disposed in a non-light emitting area adjacent to the pixel area, a first refractive layer covering the first black matrix pattern layers and having a first refractive index, wherein the first refractive layer includes a convex upper surface recessed toward the light emitting element, and a second refractive layer covering the convex upper surface of the first refractive layer and having a second refractive index different from the first refractive index.

### CROSS-REFERENCE TO RELATED APPLICATION(S)

This application claims priority to and benefits of Korean Patent Application No. 10-2024-0016583 under 35 U.S.C. § 119, filed on Feb. 2, 2024, in the Korean Intellectual Property Office (KIPO), the entire contents of which are incorporated herein by reference.

### BACKGROUND

### 1. Technical Field

Embodiments relate to a display device, a method of manufacturing the display device, and an electronic device including the display device. More particularly, embodiments relate to a display device including a black matrix pattern layer, a method of manufacturing the display device, and an electronic device including the display device.

### 2. Description of the Related Art

A display device is a device that displays an image for providing visual information to a user. Among display devices, an organic light emitting diode display has recently attracted attention.

In order to improve an image reflection phenomenon or for security reasons, a viewing angle of an image displayed on the display device may be limited.

### SUMMARY

Embodiments provide a display device capable of improving display quality.

Embodiments provide a method of manufacturing the display device.

Embodiments provide an electronic device including the display device.

A display device according to an embodiment includes a light emitting element disposed in a pixel area, first black matrix pattern layers disposed in a non-light emitting area adjacent to the pixel area, a first refractive layer covering the first black matrix pattern layers, having a first refractive index, wherein the first refractive layer may include a convex upper surface recessed toward the light emitting element, and a second refractive layer covering the convex upper surface of the first refractive layer and having a second refractive index different from the first refractive index.

In an embodiment, the second refractive index may be greater than the first refractive index.

In an embodiment, the first refractive index may be in a range of about 1.5 to about 1.55, and the second refractive index may be in a range of about 1.6 to about 1.7.

In an embodiment, the first refractive layer may include the convex upper surface recessed toward the light emitting element in the pixel area.

In an embodiment, the display device may further include second black matrix pattern layers disposed on the first refractive layer in the non-light emitting area.

In an embodiment, the second refractive layer may cover the second black matrix pattern layers.

In an embodiment, each of the first refractive layer and the second refractive layer may include an organic material.

In an embodiment, the first refractive layer may include a first portion disposed in the pixel area and a second portion disposed in the non-light emitting area.

In an embodiment, the first portion of the first refractive layer and the second portion of the first refractive layer may include different materials.

A display device according to an embodiment may include a first light emitting element disposed in a (1-1)th sub-pixel area, a second light emitting element disposed in a (2-1)th sub-pixel area adjacent to the (1-1)th sub-pixel area in a first direction in plan view, a (1-1)th black matrix pattern layer adjacent to the (1-1)th sub-pixel area including the first light emitting element in a direction opposite to the first direction in plan view, and extending in a second direction intersecting the first direction, a (2-1)th black matrix pattern layer disposed on the first light emitting element and extending in the second direction to cross the (1-1)th sub-pixel area in plan view, (3-1)th black matrix pattern layers disposed in a non-light emitting area adjacent to the (2-1)th sub-pixel area including the second light emitting element and extending in the first direction, a (1-1)th refractive layer disposed on the first light emitting element, covering the (1-1)th black matrix pattern layer and the (2-1)th black matrix pattern layer, having a first refractive index, the (1-1)th refractive layer including a convex upper surface recessed toward the first light emitting element, and a (1-2)th refractive layer covering the upper surface of the (1-1)th refractive layer on the (1-1)th refractive layer and having a second refractive index different from the first refractive index.

In an embodiment, the display device may further include a (4-1)th black matrix pattern layer disposed between the (1-1)th sub-pixel area and the (2-1)th sub-pixel area, and extending in the second direction.

In an embodiment, the (1-1)th refractive layer may cover the (4-1)th black matrix pattern layer.

In an embodiment, the display device may further include a (1-2)th black matrix pattern layer disposed on the (1-1)th refractive layer and overlapping the (1-1)th black matrix pattern layer in plan view, a (2-2)th black matrix pattern layer disposed on the (1-1)th refractive layer and overlapping the (2-1)th black matrix pattern layer in plan view, and a (4-2)th black matrix pattern layer disposed on the (1-1)th refractive layer and overlapping the (4-1)th black matrix pattern layer in plan view.

In an embodiment, the (1-2)th refractive layer may cover the (1-2)th black matrix pattern layer, the (2-2)th black matrix pattern layer, and the (4-2)th black matrix pattern layer.

In an embodiment, the (1-1)th refractive layer may include the convex upper surface recessed toward the first light emitting element between the (1-2)th black matrix pattern layer and the (2-2)th black matrix pattern layer.

In an embodiment, the (1-1)th refractive layer may include the convex upper surface recessed toward the first light emitting element between the (2-2)th black matrix pattern layer and the (4-2)th black matrix pattern layer.

In an embodiment, the display device may further include a (2-1)th refractive layer covering the (3-1)th black matrix pattern layers, and having a convex upper surface recessed toward the second light emitting element.

In an embodiment, the (2-1)th refractive layer may have the first refractive index.

In an embodiment, the display device may further include a (2-2)th refractive layer covering the convex upper surface of the (2-1)th refractive layer on the (2-1)th refractive layer and having the second refractive index.

In an embodiment, the second refractive index may be greater than the first refractive index.

In an embodiment, the first refractive index may be in a range of about 1.5 to about 1.55, and the second refractive index may be in a range of about 1.6 to about 1.7.

In an embodiment, the display device may further include (3-2)th black matrix pattern layers disposed on the (2-1)th refractive layer and overlapping the (3-1)th black matrix pattern layers in plan view.

In an embodiment, the (2-2)th refractive layer may cover the (3-2)th black matrix pattern layers.

A method of manufacturing a display device according to an embodiment may include forming a light emitting element in a pixel area, forming a first preliminary black matrix layer to cover the light emitting element, forming a first preliminary refractive layer on the first preliminary black matrix layer, forming a second preliminary black matrix layer on the first preliminary refractive layer, forming an opening by removing portions of the first preliminary black matrix layer, the first preliminary refractive layer, and the second preliminary black matrix layer, forming first refractive pattern layers filling at least a portion of the opening, having a convex upper surface recessed toward the light emitting element, the first refractive pattern layers having a first refractive index, and forming a second refractive layer covering the convex upper surface of the first refractive pattern layers and having a second refractive index different from the first refractive index.

In an embodiment, the second refractive index may be greater than the first refractive index.

In an embodiment, the forming of the opening may include forming a metal layer and a photoresist layer on the second preliminary black matrix layer, removing a portion of the metal layer and the photoresist layer overlapping the pixel area in plan view, and removing portions of the first preliminary black matrix layer, the first preliminary refractive layer, and the second preliminary black matrix layer overlapping the pixel area in plan view.

In an embodiment, the first preliminary refractive layer and the first refractive pattern layers may include a same material.

In an embodiment, each of first black matrix pattern layers, second refractive pattern layers, and second black matrix pattern layers may be formed through the forming of the opening by removing the portions of the first preliminary black matrix layer, the first preliminary refractive layer, and the second preliminary black matrix layer.

In an embodiment, the convex upper surface of the first refractive pattern layers may be formed below the second black matrix pattern layers.

An electronic device according to an embodiment includes a light emitting element disposed in a pixel area, first black matrix pattern layers disposed in a non-light emitting area adjacent to the pixel area, a first refractive layer covering the first black matrix pattern layers, having a first refractive index, wherein the first refractive layer may include a convex upper surface recessed toward the light emitting element, a second refractive layer covering the convex upper surface of the first refractive layer and having a second refractive index different from the first refractive index, and a memory device configured to store data.

A display device according to an embodiment may include a light emitting element disposed in a pixel area, first black matrix pattern layers disposed in a non-light emitting areas adjacent to the pixel area on the light emitting element, a first refractive layer covering the first black matrix pattern layers, having a first refractive index, wherein the first refractive layer has a convex upper surface recessed toward the light emitting element, and a second refractive layer covering the upper surface of the first refractive layer on the first refractive layer and having a second refractive index different from the first refractive index.

Accordingly, front light emitting efficiency of the display device may be improved.

### BRIEF DESCRIPTION OF THE DRAWINGS

Illustrative, non-limiting embodiments will be more clearly understood from the following detailed description in conjunction with the accompanying drawings.

FIG. 1 is a schematic plan view illustrating a display device according to an embodiment.

FIG. 2 is an enlarged schematic plan view illustrating an example of an area A of FIG. 1.

FIG. 3 is a schematic cross-sectional view of the display device of FIG. 2 taken along line I-I.

FIG. 4 is an enlarged schematic cross-sectional view of an area X of FIG. 3.

FIG. 5 is a schematic cross-sectional view illustrating an area X of FIG. 3 and an optical path.

FIGS. 6, 7, 8, 9, 10, 11, 12, 13, 14, 15, and 16 are schematic cross-sectional views illustrating a method of manufacturing the display device of FIG. 3.

FIG. 17 is a schematic plan view illustrating another example of an area A of FIG. 1.

FIG. 18 is a schematic diagram illustrating an interior of a vehicle to which the display device of FIG. 17 is applied.

FIG. 19 is a schematic cross-sectional view of the display device of FIG. 18 taken along line II-II′.

FIG. 20 is a schematic cross-sectional view of the display device of FIG. 18 taken along line III-III′.

FIG. 21 is a block diagram illustrating an electronic device according to embodiments.

FIG. 22 is a diagram illustrating an example in which the electronic device of FIG. 21 is implemented as a smart phone.

### DETAILED DESCRIPTION OF THE EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element or a layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B.

Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

Hereinafter, display devices in accordance with embodiments will be described in more detail with reference to the accompanying drawings. The same reference numerals are used for the same components in the drawings, and redundant descriptions of the same components will be omitted.

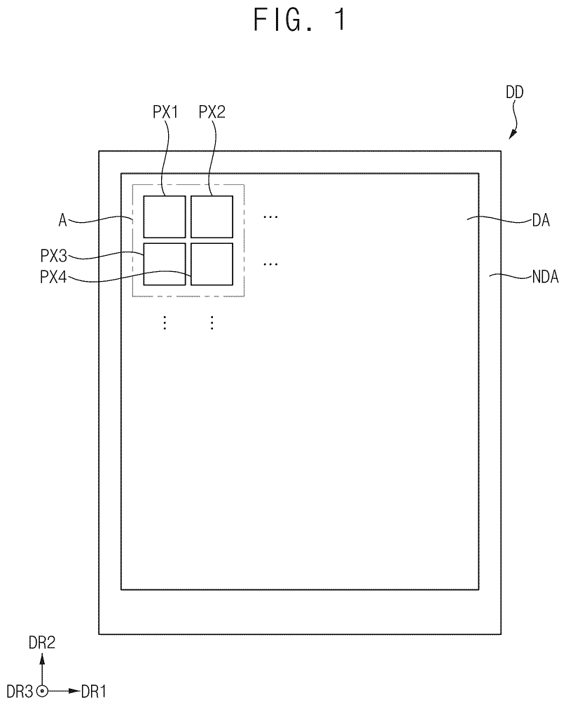

FIG. 1 is a schematic plan view illustrating a display device according to an embodiment.

Referring to FIG. 1, a display device DD according to an embodiment may include a display area DA and a non-display area NDA.

Pixel areas may be disposed in the display area DA. For example, a first pixel area PX1, a second pixel area PX2, a third pixel area PX3, and a fourth pixel area PX4 may be disposed in the display area DA. Each of the first pixel area PX1, the second pixel area PX2, the third pixel area PX3, and the fourth pixel area PX4 may emit light.

The pixel areas may be repeatedly arranged along a first direction DR1 and a second direction DR2 intersecting the first direction DR1. For example, the second pixel area PX2 may be adjacent to the first pixel area PX1 in the first direction DR1. The third pixel area PX3 may be adjacent to the first pixel area PX1 in a direction opposite to the second direction DR2. The fourth pixel area PX4 may be adjacent to the second pixel area PX2 in a direction opposite to the second direction DR2, and may be adjacent to the third pixel area PX3 in the first direction DR1.

The non-display area NDA may be disposed around the display area DA. For example, the non-display area NDA may surround at least a portion of the display area DA. A driver may be disposed in the non-display area NDA. The driver may provide signals or voltages to the pixel areas. For example, the driver may include a data driver, a gate driver, and the like. The non-display area NDA may not display an image.

In the description, the first direction DR1 and the second direction DR2 intersecting the first direction DR1 may be defined. For example, the second direction DR2 may be perpendicular to the first direction DR1. However, embodiments are not limited thereto, and the second direction DR2 may form an acute angle or an obtuse angle with the first direction DR1. For example, a third direction DR3 intersecting a plane formed by the first direction DR1 and the second direction DR2 may be defined. For example, the third direction DR3 may be perpendicular to the plane formed by the first direction DR1 and second direction DR2. However, embodiments are not limited thereto, and the third direction DR3 may form an acute angle or an obtuse angle with the plane formed by the first direction DR1 and second direction DR2.

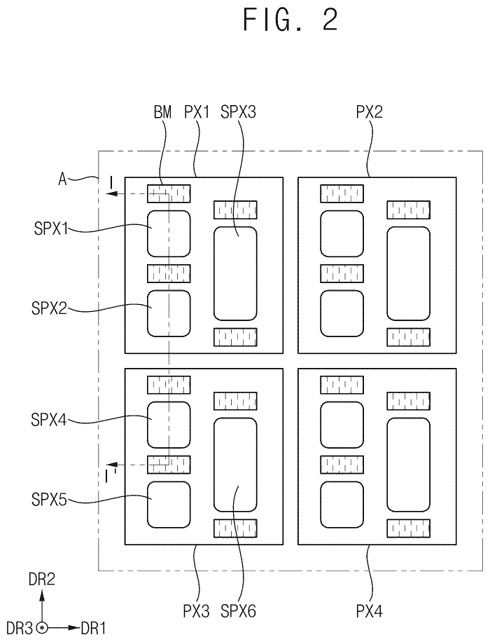

FIG. 2 is an enlarged schematic plan view illustrating an example of an area A of FIG. 1.

Referring to FIG. 2, the first pixel area PX1 may include a first sub-pixel area SPX1, a second sub-pixel area SPX2, and a third sub-pixel area SPX3. The first sub-pixel area SPX1 may emit first light, the second sub-pixel area SPX2 may emit second light, and the third sub-pixel area SPX3 may emit third light. For example, the first light may be red light, the second light may be green light, and the third light may be blue light.

However, embodiments are not limited thereto. For example, the first light may be green light, the second light may be red light, and the third light may be blue light. As each of the first sub-pixel area SPX1, the second sub-pixel area SPX2, and the third sub-pixel area SPX3 emits light, the first pixel area PX1 may emit light of a specific wavelength.

The third pixel area PX3 may include a fourth sub-pixel area SPX4, a fifth sub-pixel area SPX5, and a sixth sub-pixel area SPX6. The fourth sub-pixel area SPX4 may emit fourth light, the fifth sub-pixel area SPX5 may emit fifth light, and the sixth sub-pixel area SPX6 may emit sixth light. For example, the fourth light may be red light, the fifth light may be green light, and the sixth light may be blue light. However, embodiments are not limited thereto. For example, the fourth light may be green light, the fifth light may be red light, and the sixth light may be blue light. As each of the fourth sub-pixel area SPX4, the fifth sub-pixel area SPX5, and the sixth sub-pixel area SPX6 emits light, the third pixel area PX3 may emit light of a specific wavelength.

In an embodiment, the display device (e.g., the display device DD of FIG. 1) may further include black matrix pattern layers BM. The black matrix pattern layers BM may not overlap the first sub-pixel area SPX1, the second sub-pixel area SPX2, the third sub-pixel area SPX3, the fourth sub-pixel area SPX4, the fifth sub-pixel area SPX5, and the sixth sub-pixel area SPX6 in plan view.

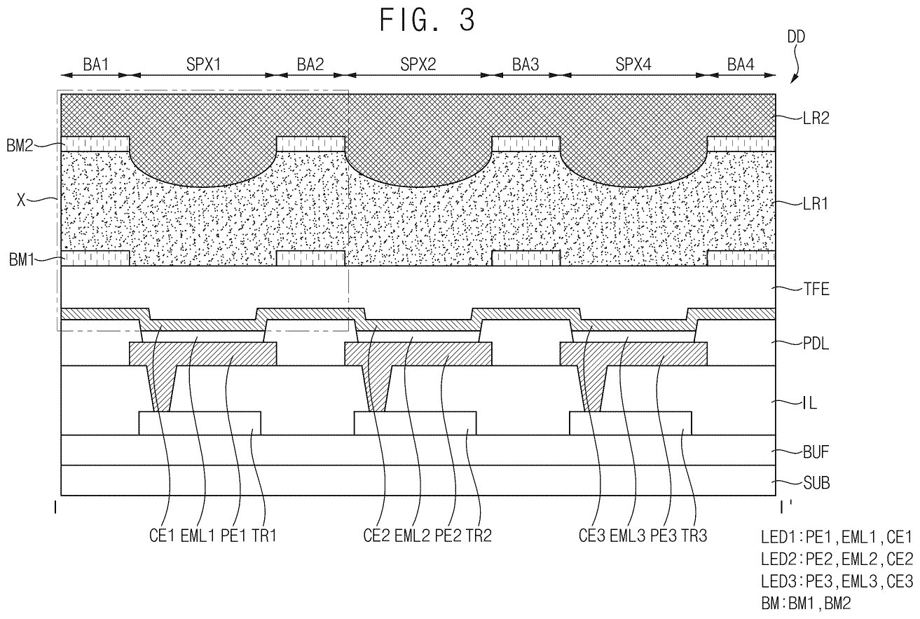

For example, some of the black matrix pattern layers BM may be disposed in a first non-light emitting area (e.g., a first non-light emitting area BA1 of FIG. 3) adjacent to the first sub-pixel area SPX1 in the second direction DR2 in plan view. For example, some of the black matrix pattern layers BM may be disposed in a second non-light emitting area (e.g., a second non-light emitting area BA2 of FIG. 3) adjacent to the second sub-pixel area SPX2 in the second direction DR2 in plan view. For example, some of the black matrix pattern layers BM may be disposed in a portion adjacent to the third sub-pixel area SPX3 in the second direction DR2 in plan view and a portion adjacent to the third sub-pixel area SPX3 in a direction opposite to the second direction DR2 in plan view.

For example, some of the black matrix pattern layers BM may be disposed in a third non-light emitting area (e.g., a third non-light emitting area BA3 of FIG. 3) adjacent to the fourth sub-pixel area SPX4 in the second direction DR2 in plan view. For example, some of the black matrix pattern layers BM may be disposed in a fourth non-light emitting area (e.g., the fourth non-light emitting area BA4 of FIG. 3) adjacent to the fourth sub-pixel area SPX4 in the second direction DR2 in plan view. For example, some of the black matrix pattern layers BM may be disposed in a portion adjacent to the sixth sub-pixel area SPX6 in the second direction DR2 in plan view and a portion adjacent to the sixth sub-pixel area SPX6 in the direction opposite to the second direction DR2 in plan view.

The second pixel area PX2 may have substantially the same structure as the first pixel area PX1 and the third pixel area PX3. The fourth pixel area PX4 may have substantially the same structure as the first pixel area PX1 and the third pixel area PX3.

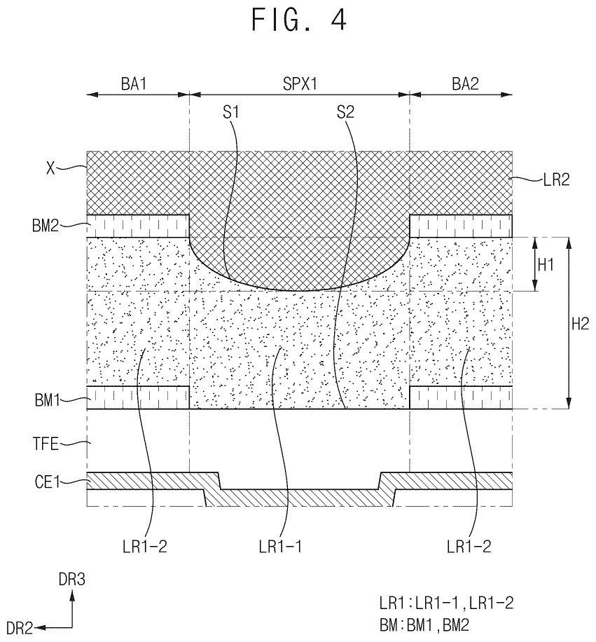

FIG. 3 is a schematic cross-sectional view of the display device of FIG. 2 taken along line I-I. FIG. 4 is an enlarged schematic cross-sectional view of an area X of FIG. 3.

Referring to FIG. 3, the display device DD according to an embodiment may include a substrate SUB, a buffer layer BUF, an insulating layer IL, a first transistor TR1, a second transistor TR2, a third transistor TR3, a first light emitting element LED1, a second light emitting element LED2, a third light emitting element LED3, a pixel defining layer PDL, an encapsulation layer TFE, black matrix pattern layers BM, a first refractive layer LR1, and a second refractive layer LR2.

The substrate SUB may include a transparent material or an opaque material. The substrate SUB may be formed of a transparent resin substrate. Example of the transparent resin substrate may include a polyimide substrate. For example, the polyimide substrate may include a first organic layer, a first barrier layer, a second organic layer, and the like.

In another example, the substrate SUB may include a quartz substrate (e.g., a synthetic quartz substrate, a fluorine-doped quartz substrate), a calcium fluoride substrate, a sodalime glass substrate, a non-alkali glass substrate, or the like. These materials may be used alone or in combination with each other.

The buffer layer BUF may be disposed on the substrate SUB. The buffer layer BUF may prevent metal atoms or impurities from diffusing from the substrate SUB to the first transistor TR1, the second transistor TR2, and the third transistor TR3. For example, the buffer layer BUF may improve flatness of a surface of the substrate SUB when the surface of the substrate SUB is not uniform.

For example, the buffer layer BUF may include an inorganic material such as silicon oxide, silicon nitride, silicon carbide, silicon oxynitride, silicon oxycarbide, or the like. These materials may be used alone or in combination with each other.

The first transistor TR1, the second transistor TR2, and the third transistor TR3 may be disposed on the buffer layer BUF. For example, the first transistor TR1 may be disposed in at least a portion of the first sub-pixel area SPX1, the second transistor TR2 may be disposed in at least a portion of the second sub-pixel area SPX2, and the third transistor TR3 may be disposed in at least a portion of the fourth sub-pixel area SPX4.

The first transistor TR1 may include a first active pattern layer, a first gate electrode, a first source electrode, and a first drain electrode. The second transistor TR2 may include a second active pattern layer, a second gate electrode, a second source electrode, and a second drain electrode. The third transistor TR3 may include a third active pattern layer, a third gate electrode, a third source electrode, and a third drain electrode.

For example, each of the first transistor TR1, the second transistor TR2, and the third transistor TR3 may include polycrystalline silicon or a metal oxide semiconductor.

The metal oxide semiconductor may include a binary compound (“ABₓ”), a ternary compound (“ABₓC_{y}”), a quaternary compound (“ABₓC_{y}D_{z}”), or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like. These materials may be used alone or in combination with each other.

For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The insulating layer IL may be disposed on the buffer layer BUF. The insulating layer IL may cover the first transistor TR1, the second transistor TR2, and the third transistor TR3. For example, the insulating layer IL may include at least one inorganic insulating layer and at least one organic insulating layer.

For example, the inorganic insulating layer may include silicon oxide, silicon nitride, silicon carbide, silicon oxynitride, silicon oxycarbide, or the like. These materials may be used alone or in combination with each other.

For example, the organic insulating layer may include a photoresist, a polyacryl-based resin, a polyimide-based resin, a polyamide-based resin, a siloxane-based resin, an acryl-based resin, an epoxy-based resin, or the like. These materials may be used alone or in combination with each other.

A first pixel electrode PE1, a second pixel electrode PE2, and a third pixel electrode PE3 may be disposed on the insulating layer IL. The first pixel electrode PE1 may be disposed in the first sub-pixel area SPX1, the second pixel electrode PE2 may be disposed in the second sub-pixel area SPX2, and the third pixel electrode PE3 may be disposed in the fourth sub-pixel area SPX4.

The first pixel electrode PE1 may be connected to the first transistor TR1 through a first contact hole formed by removing a portion of the insulating layer IL. The second pixel electrode PE2 may be connected to the second transistor TR2 through a second contact hole formed by removing a portion of the insulating layer IL. The third pixel electrode PE3 may be connected to the third transistor TR3 through a third contact hole formed by removing a portion of the insulating layer IL.

For example, each of the first pixel electrode PE1, the second pixel electrode PE2, and the third pixel electrode PE3 may include a metal, an alloy, a metal nitride, a conductive metal oxide, a transparent conductive material, or the like. These materials may be used alone or in combination with each other.

For example, the first pixel electrode PE1 may operate (or function) as an anode of the first light emitting element LED1. The second pixel electrode PE2 may operate (or function) as an anode of the second light emitting element LED2. The third pixel electrode PE3 may operate (or function) as an anode of the third light emitting element LED3.

The pixel defining layer PDL may be disposed on the insulating layer IL, the first pixel electrode PE1, the second pixel electrode PE2, and the third pixel electrode PE3. For example, the pixel defining layer PDL may be disposed in the first non-light emitting area BA1, the second non-light emitting area BA2, the third non-light emitting area BA3, and the fourth non-light emitting area BA4.

The pixel defining layer PDL may cover side portion of each of the first pixel electrode PE1, the second pixel electrode PE2, and the third pixel electrode PE3. For example, the pixel defining layer PDL may expose an upper surface of each of the first pixel electrode PE1, the second pixel electrode PE2, and the third pixel electrode PE3.

For example, the pixel defining layer PDL may include an organic material and/or an inorganic material. In an embodiment, the pixel defining layer PDL may include an organic material. For example, the pixel defining layer PDL may include a photoresist, a polyacrylic resin, a polyimide resin, a polyamide resin, a siloxane resin, an acrylic resin, an epoxy resin, or the like. These materials may be used alone or in combination with each other.

The second non-light emitting area BA2 may be disposed between the first sub-pixel area SPX1 and the second sub-pixel area SPX2. The second non-light emitting area BA2 may be spaced apart from the first non-light emitting area BA1 with the first sub-pixel area SPX1 interposed therebetween. The third non-light emitting area BA3 may be disposed between the second sub-pixel area SPX2 and the fourth sub-pixel area SPX4. The third non-light emitting area BA3 may be spaced apart from the second non-light emitting area BA2 with the second sub-pixel area SPX2 interposed therebetween. For example, the third non-light emitting area BA3 may be spaced apart from the fourth non-light emitting area BA4 with the fourth sub-pixel area SPX4 interposed therebetween.

A first light emitting layer EML1 may be disposed on the first pixel electrode PE1. For example, the first light emitting layer EML1 may be disposed in the first sub-pixel area SPX1. A second light emitting layer EML2 may be disposed on the second pixel electrode PE2. For example, the second light emitting layer EML2 may be disposed in the second sub-pixel area SPX2. A third light emitting layer EML3 may be disposed on the third pixel electrode PE3. For example, the third light emitting layer EML3 may be disposed in the fourth sub-pixel area SPX4.

For example, holes provided in the first pixel electrode PE1 and electrons provided in the first common electrode CE1 may form first excitons in the first light emitting layer EML1. The first light emitting layer EML1 may emit light as the first excitons change from the excited state to the ground state.

Holes provided in the second pixel electrode PE2 and electrons provided in the second common electrode CE2 may form second excitons in the second light emitting layer EML2. The second light emitting layer EML2 may emit light as the second excitons change from the excited state to the ground state.

Holes provided in the third pixel electrode PE3 and the electrons provided in the third common electrode CE3 may form third excitons in the third light emitting layer EML3. The third light emitting layer EML3 may emit light as the third excitons change from the excited state to the ground state.

A first common electrode CE1 may be disposed on the first light emitting layer EML1. For example, the first common electrode CE1 may be disposed in the first sub-pixel area SPX1. A second common electrode CE2 may be disposed on the second light emitting layer EML2. For example, the second common electrode CE2 may be disposed in the second sub-pixel area SPX2. A third common electrode CE3 may be disposed on the third light emitting layer EML3. For example, the third common electrode CE3 may be disposed in the fourth sub-pixel area SPX4.

In an embodiment, the first common electrode CE1 may be connected to the second common electrode CE2, and the second common electrode CE2 may be connected to the third common electrode CE3. For example, the first common electrode CE1, the second common electrode CE2, and the third common electrode CE3 may be integral with each other.

However, embodiments are not limited thereto, and in another embodiment, the first common electrode CE1 may be separated from the second common electrode CE2, and the second common electrode CE2 may be separated from the third common electrode CE3.

For example, each of the first common electrode CE1, the second common electrode CE2, and the third common electrode CE3 may include a metal, an alloy, a metal nitride, a conductive metal oxide, a transparent conductive material, or the like. These materials may be used alone or in combination with each other.

For example, the first common electrode CE1 may operate (or function) as a cathode of the first light emitting element LED1. The second common electrode CE2 may operate (or function) as a cathode of the second light emitting element LED2. The third common electrode CE3 may operate (or function) as a cathode of the third light emitting element LED3.

The first light emitting element LED1 may include the first pixel electrode PE1, the first light emitting layer EML1, and the first common electrode CE1. The first light emitting element LED1 may be disposed in the first sub-pixel area SPX1. The second light emitting element LED2 may include the second pixel electrode PE2, the second light emitting layer EML2, and the second common electrode CE2. The second light emitting element LED2 may be disposed in the second sub-pixel area SPX2. The third light emitting element LED3 may include the third pixel electrode PE3, the third light emitting layer EML3, and the third common electrode CE3. The third light emitting element LED3 may be disposed in the fourth sub-pixel area SPX4.

The encapsulation layer TFE may be disposed on the first common electrode CE1, the second common electrode CE2, and the third common electrode CE3. The encapsulation layer TFE may prevent impurities, moisture, and the like from penetrating or permeating into the first light emitting element LED1, the second light emitting element LED2, and the third light emitting element LED3.

For example, the encapsulation layer TFE may include at least one inorganic encapsulation layer and at least one organic encapsulation layer. The inorganic encapsulation layer may include silicon oxide, silicon nitride, silicon oxynitride, or the like. These materials may be used alone or in combination with each other. The organic encapsulation layer may include a cured polymer material such as polyacrylate.

Referring to FIGS. 3 and 4, the black matrix pattern layers BM may include first black matrix pattern layers BM1 and second black matrix pattern layers BM2. The first black matrix pattern layers BM1 may be disposed on the encapsulation layer TFE. The first black matrix pattern layers BM1 may overlap the first non-light emitting area BA1, the second non-light emitting area BA2, the third non-light emitting area BA3, and the fourth non-light emitting area BA4 in plan view. The first black matrix pattern layers BM1 may be spaced apart from each other in plan view. For example, the first black matrix pattern layers BM1 may be spaced apart from each other in the second direction DR2 in plan view.

In an embodiment, the first black matrix pattern layers BM1 may include an inorganic material. For example, the first black matrix pattern layers BM1 may include an inorganic material such as molybdenum-tantalum oxide (“MTO”). For example, the first black matrix pattern layers BM1 may have an MTO monolayer structure.

In another example, the first black matrix pattern layers BM1 may have a double layer structure including MTO/Mo, MTO/Cu, MTO/Al, or the like. These materials may be used alone or in combination with each other.

However, embodiments are not limited thereto, and the first black matrix pattern layers BM1 may include various materials having relatively low transmittance and reflectance and relatively high absorption. For example, the first black matrix pattern layers BM1 may include an organic material including a black pigment.

The first refractive layer LR1 may be disposed on the encapsulation layer TFE. The first refractive layer LR1 may cover the first black matrix pattern layers BM1. The first refractive layer LR1 may include an upper surface and a lower surface. The lower surface of the first refractive layer LR1 may be a surface facing the substrate SUB. The upper surface of the first refractive layer LR1 may be a surface opposite to the lower surface.

For example, the first refractive layer LR1 may include an upper surface S1 and a lower surface S2 in the first sub-pixel area SPX1. The lower surface S2 of the first refractive layer LR1 may be a surface facing the substrate SUB in the first sub-pixel area SPX1. For example, the lower surface S2 of the first refractive layer LR1 may be a surface facing the first light emitting element LED1. The upper surface S1 of the first refractive layer LR1 may be a surface opposite to the lower surface S2 in the first sub-pixel area SPX1. The upper surface S1 of the first refractive layer LR1 may be a boundary surface at which the second refractive layer LR2, which will be described later, and the first refractive layer LR1 are in contact with each other.

In an embodiment, the upper surface S1 of the first refractive layer LR1 may be a convex surface. For example, the upper surface S1 of the first refractive layer LR1 may be a convex surface recessed toward the first light emitting element LED1. For example, the upper surface S1 of the first refractive layer LR1 may be a downwardly convex surface.

The upper surface S1 of the first refractive layer LR1 may have a first height H1. The first height H1 may be a separation distance in the third direction DR3 between a plane extending from a lower surface of the second black matrix pattern layers BM2 to be described later and a portion of the upper surface S1 of the first refractive layer LR1 closest to the lower surface S2.

For example, the first refractive layer LR1 may have a second height H2. The second height H2 may be a separation distance in the third direction DR3 between the lower surface S2 of the first refractive layer LR1 and the plane extending from the lower surface of the second black matrix pattern layers BM2.

In an embodiment, the first height H1 may be equal to or greater than about ⅓ and equal to or less than about ½ of the second height H2 or may be in a range of about ⅓ to about ½. For example, the first height H1 may be about ⅓ of the second height H2. However, embodiments are not limited thereto, and the first height H1 and the second height H2 may be appropriately changed.

In an embodiment, the first refractive layer LR1 may include an organic material. For example, the first refractive layer LR1 may include an acrylic resin, a polyacrylic resin, a polyimide resin, an epoxy resin, a melanin resin, or the like. These materials may be used alone or in combination with each other. However, embodiments are not limited thereto, and the first refractive layer LR1 may include other types of organic materials.

The first refractive layer LR1 may have a first refractive index. In an embodiment, the first refractive index of the first refractive layer LR1 may be equal to or greater than about 1.5 and equal to or less than about 1.55 or may be in a range of about 1.5 to about 1.55. For example, the first refractive index may be about 1.5. However, these values are examples, and the first refractive index may be appropriately changed.

The first refractive layer LR1 may include a first portion LR1-1 and a second portion LR1-2. The first portion LR1-1 of the first refractive layer LR1 may overlap the first sub-pixel area SPX1 in plan view. The second portion LR1-2 of the first refractive layer LR1 may overlap the first non-light emitting area BA1 and the second non-light emitting area BA2 in plan view.

In an embodiment, the first portion LR1-1 of the first refractive layer LR1 and the second portion LR1-2 of the first refractive layer LR1 may include the same material. However, embodiments are not limited thereto, and in another embodiment, the first portion LR1-1 of the first refractive layer LR1 and the second portion LR1-2 of the first refractive layer LR1 may include different materials.

The second black matrix pattern layers BM2 may be disposed on the first refractive layer LR1. The second black matrix pattern layers BM2 may overlap the first non-light emitting area BA1, the second non-light emitting area BA2, the third non-light emitting area BA3, and the fourth non-light emitting area BA4 in plan view. The second black matrix pattern layers BM2 may be spaced apart from each other in plan view. For example, the second black matrix pattern layers BM2 may be spaced apart from each other in the second direction DR2 in plan view. For example, the second black matrix pattern layers BM2 may overlap the first black matrix pattern layers BM1 in plan view.

In an embodiment, the second black matrix pattern layers BM2 may include an inorganic material. For example, the second black matrix pattern layers BM2 may include an inorganic material such as molybdenum-tantalum oxide (“MTO”). For example, the second black matrix pattern layers BM2 may have an MTO monolayer structure.

In another example, the second black matrix pattern layers BM2 may have a double layer structure including MTO/Mo, MTO/Cu, MTO/Al, or the like. These materials may be used alone or in combination with each other.

However, embodiments are not limited thereto, and the second black matrix pattern layers BM2 may include various materials having relatively low transmittance and reflectance and relatively high absorption. For example, the second black matrix pattern layers BM2 may include an organic material including a black pigment.

In an embodiment, the second black matrix pattern layers BM2 and the first black matrix pattern layers BM1 may include substantially the same material. However, embodiments are not limited thereto, and in another embodiment, the second black matrix pattern layers BM2 and the first black matrix pattern layers BM1 may include different materials. For example, the first black matrix pattern layers BM1 may have an MTO monolayer structure, and the second black matrix pattern layers BM2 may include an organic material including a black pigment.

The second refractive layer LR2 may be disposed on the first refractive layer LR1 and the second black matrix pattern layers BM2. The second refractive layer LR2 may cover the second black matrix pattern layers BM2. For example, the second refractive layer LR2 may cover the first refractive layer LR1. For example, the second refractive layer LR2 may cover the upper surface of the first refractive layer LR1. For example, the second refractive layer LR2 may cover the upper surface S1 of the first refractive layer LR1 in the first sub-pixel area SPX1.

In an embodiment, the second refractive layer LR2 may include an organic material. For example, the second refractive layer LR2 may include a polysiloxane-based resin, a polyacrylic-based resin, a polyimide-based resin, an epoxy resin, an acrylic resin, or the like. These materials may be used alone or in combination with each other. However, embodiments are not limited thereto, and the second refractive layer LR2 may include other types of organic materials.

In an embodiment, the second refractive layer LR2 may further include high refractive particles. The high refractive particles may be dispersed in the second refractive layer LR2 to increase a refractive index of the second refractive layer LR2. For example, the high refractive particles may include titanium dioxide, zirconium dioxide, zinc oxide, or the like. These materials may be used alone or in combination with each other.

The second refractive layer LR2 may have a second refractive index. In an embodiment, the second refractive index of the second refractive layer LR2 may be equal to or greater than about 1.6 and equal to or less than about 1.7 or may be in a range of about 1.6 to about 1.7. For example, the second refractive index may be about 1.6. However, these values are examples, and the second refractive index may be appropriately changed. For example, the second refractive index may be greater than the first refractive index.

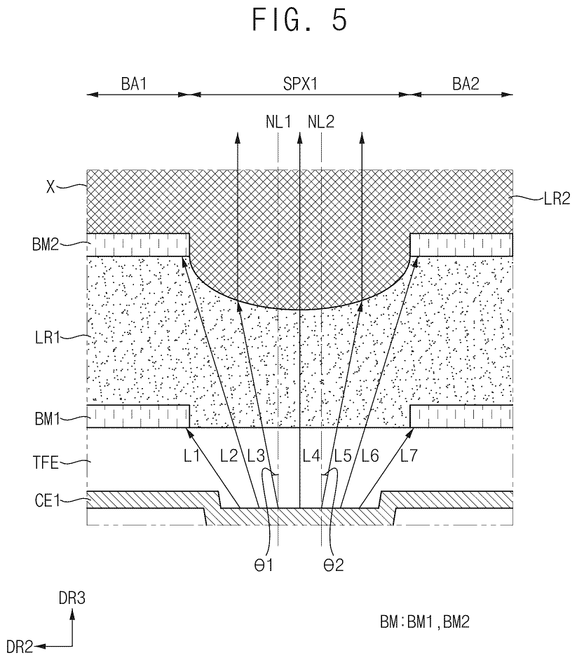

FIG. 5 is a schematic cross-sectional view illustrating an area X of FIG. 3 and an optical path. Specifically, FIG. 5 is a schematic cross-sectional view illustrating an optical path emitted from the first light emitting element of FIG. 3.

Referring to FIG. 5, the first light emitting device (e.g., the first light emitting element LED1 of FIG. 3) may emit light to the black matrix pattern layers BM, the first refractive layer LR1, and the second refractive layer LR2. For example, the first light emitting element may emit a first light L1, a second light L2, a third light L3, a fourth light L4, a fifth light L5, a sixth light L6, and a seventh light L7.

The first light L1 and the seventh light L7 may be blocked or absorbed by the first black matrix pattern layers BM1. For example, the second light L2 and the sixth light L6 may be blocked or absorbed by the second black matrix pattern layers BM2. For example, the first black matrix pattern layers BM1 and the second black matrix pattern layers BM2 may block or absorb a portion of the light emitted to lateral side from a light emitting element. For example, the first black matrix pattern layers BM1 and the second black matrix pattern layers BM2 may block or absorb a portion of the light emitted to lateral side from the first light emitting element. Accordingly, the display device (e.g., the display device DD of FIG. 3) may have a narrow viewing angle. For example, the display device may have a narrow viewing angle in a second direction DR2 and a direction opposite to the second direction DR2.

The third light L3 may enter the first refractive layer LR1 at a first angle θ1 relative to a first normal line NL1 perpendicular to the first common electrode CE1. For example, the first angle θ1 may be an acute angle. The third light L3 may be refracted at a boundary surface where the first refractive layer LR1 and the second refractive layer LR2 contact each other. For example, the third light L3 may be refracted at the upper surface S1 of the first refractive layer LR1. As described above, the second refractive index of the second refractive layer LR2 may be higher than the first refractive index of the first refractive layer LR1. Accordingly, the third light L3 may be refracted to be substantially parallel to the first normal line NL1 at the upper surface S1 of the first refractive layer LR1. For example, the third light L3 may be refracted to be substantially parallel to the fourth light L4 emitted while being perpendicular to the first common electrode CE1.

The fifth light L5 may enter the first refractive layer LR1 at a second angle θ2 relative to a second normal NL2 perpendicular to the first common electrode CE1. For example, the second angle θ2 may be an acute angle. The fifth light L5 may be refracted at a boundary surface where the first refractive layer LR1 and the second refractive layer LR2 contact each other. For example, the fifth light L5 may be refracted at the upper surface S1 of the first refractive layer LR1. The fifth light L5 may be refracted to be substantially parallel to the second normal NL2 at the upper surface S1 of the first refractive layer LR1. For example, the fifth light L5 may be refracted to be substantially parallel to the fourth light L4, which is emitted perpendicular to the first common electrode CE1.

As the display device includes the first refractive layer LR1 having the first refractive index and the second refractive layer LR2 having the second refractive index greater than the first refractive index, some of the light emitted to lateral side from the light emitting element may be emitted to a front of the display device. For example, some of the light emitted to the lateral side from the first light emitting element may be emitted to the front of the display device. Accordingly, front light emitting efficiency of the display device may be improved.

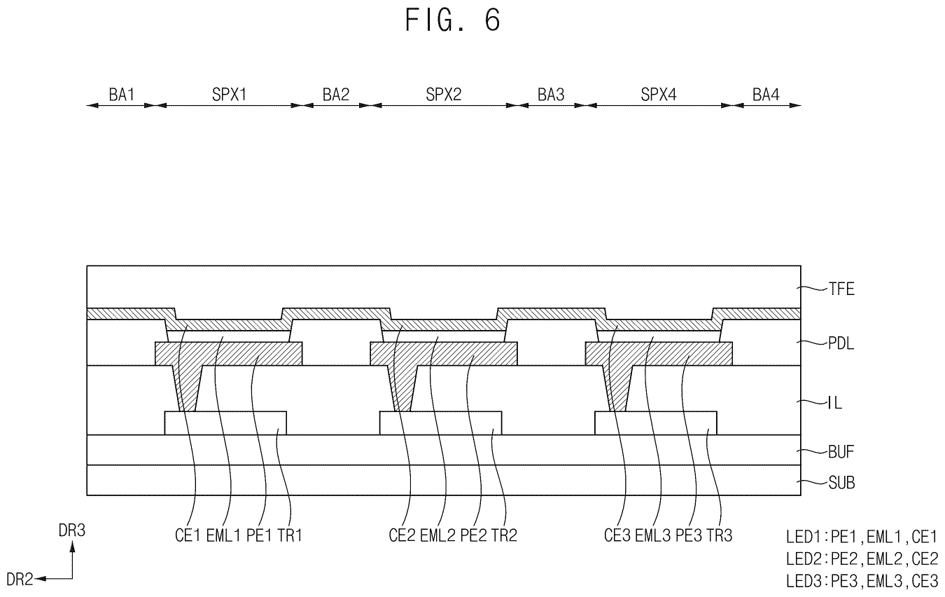

FIGS. 6, 7, 8, 9, 10, 11, 12, 13, 14, 15, and 16 are schematic cross-sectional views illustrating a method of manufacturing the display device of FIG. 3.

Referring to FIG. 6, the buffer layer BUF may be formed on the substrate SUB. For example, the substrate SUB may include a transparent material or an opaque material. The substrate SUB may be formed of a transparent resin substrate. Example of the transparent resin substrate may include a polyimide substrate. For example, the polyimide substrate may include a first organic layer, a first barrier layer, a second organic layer, and the like.

In another example, the substrate SUB may include a quartz substrate (e.g., a synthetic quartz substrate, a fluorine-doped quartz substrate), a calcium fluoride substrate, a soda-lime glass substrate, a non-alkali glass substrate, or the like. These materials may be used alone or in combination with each other.

For example, the buffer layer BUF may include an inorganic material such as silicon oxide, silicon nitride, silicon carbide, silicon oxynitride, silicon oxycarbide, or the like. These materials may be used alone or in combination with each other.

The first transistor TR1, the second transistor TR2, and the third transistor TR3 may be formed on the buffer layer BUF. The first transistor TR1 may be formed in at least a portion of the first sub-pixel area SPX1. The second transistor TR2 may be formed in at least a portion of the second sub-pixel area SPX2. The third transistor TR3 may be formed in at least a portion of the fourth sub-pixel area SPX4.

For example, each of the first transistor TR1, the second transistor TR2, and the third transistor TR3 may include polycrystalline silicon or a metal oxide semiconductor.

The metal oxide semiconductor may include a binary compound (“ABₓ”), a ternary compound (“ABₓC_{y}”), a quaternary compound (“ABₓC_{y}D_{z}”), or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like. These materials may be used alone or in combination with each other.

For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The insulating layer IL may be formed on the buffer layer BUF. The insulating layer IL may be formed to cover the first transistor TR1, the second transistor TR2, and the third transistor TR3. For example, the insulating layer IL may include at least one inorganic insulating layer and at least one organic insulating layer.

For example, the inorganic insulating layer may include silicon oxide, silicon nitride, silicon carbide, silicon oxynitride, silicon oxycarbide, or the like. These materials may be used alone or in combination with each other.

For example, the organic insulating layer may include a photoresist, a polyacryl-based resin, a polyimide-based resin, a polyamide-based resin, a siloxane-based resin, an acryl-based resin, an epoxy-based resin, or the like. These materials may be used alone or in combination with each other.

The first pixel electrode PE1, the second pixel electrode PE2, and the third pixel electrode PE3 may be formed on the insulating layer IL. The first pixel electrode PE1 may be formed in the first sub-pixel area SPX1. The second pixel electrode PE2 may be formed in the second sub-pixel area SPX2. The third pixel electrode PE3 may be formed in the fourth sub-pixel area SPX4.

The first contact hole may be formed by removing a portion of the insulating layer IL. The first pixel electrode PE1 may be connected to the first transistor TR1 through the first contact hole. The second contact hole may be formed by removing a portion of the insulating layer IL. The second pixel electrode PE2 may be connected to the second transistor TR2 through the second contact hole. The third contact hole may be formed by removing a portion of the insulating layer IL. The third pixel electrode PE3 may be connected to the third transistor TR3 through the third contact hole.

For example, each of the first pixel electrode PE1, the second pixel electrode PE2, and the third pixel electrode PE3 may include a metal, an alloy, a metal nitride, a conductive metal oxide, a transparent conductive material, or the like. These materials may be used alone or in combination with each other.

The pixel defining layer PDL may be formed on the insulating layer IL, the first pixel electrode PE1, the second pixel electrode PE2, and the third pixel electrode PE3. For example, the pixel defining layer PDL may be formed in the first non-light emitting area BA1, the second non-light emitting area BA2, the third non-light emitting area BA3, and the fourth non-light emitting area BA4.

The pixel defining layer PDL may be formed to cover side portion of each of the first pixel electrode PE1, the second pixel electrode PE2, and the third pixel electrode PE3. For example, the pixel defining layer PDL may be formed to expose the upper surface of each of the first pixel electrode PE1, the second pixel electrode PE2, and the third pixel electrode PE3.

For example, the pixel defining layer PDL may include an organic material and/or an inorganic material. In an embodiment, the pixel defining layer PDL may include an organic material. For example, the pixel defining layer PDL may include a photoresist, a polyacrylic resin, a polyimide resin, a polyamide resin, a siloxane resin, an acrylic resin, an epoxy resin, or the like. These materials may be used alone or in combination with each other.

The first light emitting layer EML1 may be formed on the first pixel electrode PE1. For example, the first light emitting layer EML1 may be formed in the first sub-pixel area SPX1. The second light emitting layer EML2 may be formed on the second pixel electrode PE2. For example, the second light emitting layer EML2 may be formed in the second sub-pixel area SPX2. The third light emitting layer EML3 may be disposed on the third pixel electrode PE3. For example, the third light emitting layer EML3 may be formed in the fourth sub-pixel area SPX4.

The first common electrode CE1 may be formed on the first light emitting layer EML1. For example, the first common electrode CE1 may be formed in the first sub-pixel area SPX1. The second common electrode CE2 may be formed on the second light emitting layer EML2. For example, the second common electrode CE2 may be formed in the second sub-pixel area SPX2. The third common electrode CE3 may be formed on the third light emitting layer EML3. For example, the third common electrode CE3 may be formed in the fourth sub-pixel area SPX4.

In an embodiment, the first common electrode CE1, the second common electrode CE2, and the third common electrode CE3 may be integral with each other. However, embodiments are not limited thereto, and in another embodiment, the first common electrode CE1 may be formed separately from the second common electrode CE2, and the second common electrode CE2 may be formed separately from the third common electrode CE3.

For example, each of the first common electrode CE1, the second common electrode CE2, and the third common electrode CE3 may include a metal, an alloy, a metal nitride, a conductive metal oxide, a transparent conductive material, or the like. These materials may be used alone or in combination with each other.

The encapsulation layer TFE may be formed on the first common electrode CE1, the second common electrode CE2, and the third common electrode CE3. For example, the encapsulation layer TFE may include at least one inorganic encapsulation layer and at least one organic encapsulation layer. For example, the inorganic encapsulation layer may include silicon oxide, silicon nitride, silicon oxynitride, or the like. These materials may be used alone or in combination with each other. The organic encapsulation layer may include a polymer cured product such as polyacrylate.

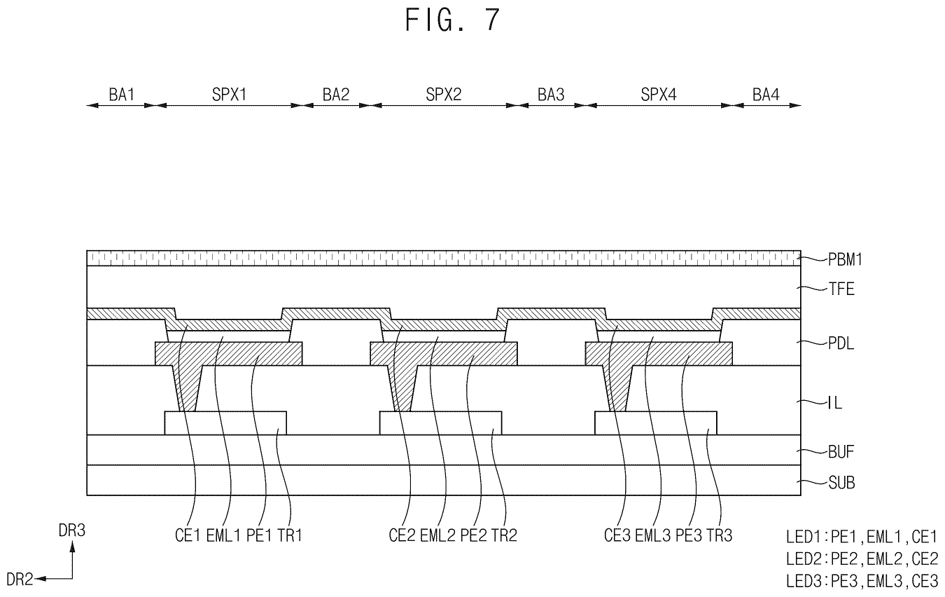

Referring to FIG. 7, a first preliminary black matrix layer PBM1 may be formed on the encapsulation layer TFE. In an embodiment, the first preliminary black matrix layer PBM1 may include an inorganic material. For example, the first preliminary black matrix layer PBM1 may include an inorganic material such as molybdenum-tantalum oxide (“MTO”). For example, the first preliminary black matrix layer PBM1 may have an MTO monolayer structure.

In another example, the first preliminary black matrix layer PBM1 may have a double layer structure including MTO/Mo, MTO/Cu, MTO/Al, or the like. These materials may be used alone or in combination with each other.

However, embodiments are not limited thereto, and the first preliminary black matrix layer PBM1 may include various materials having relatively low transmittance and reflectance and relatively high absorption. For example, the first preliminary black matrix layer PBM1 may include an organic material including a black pigment.

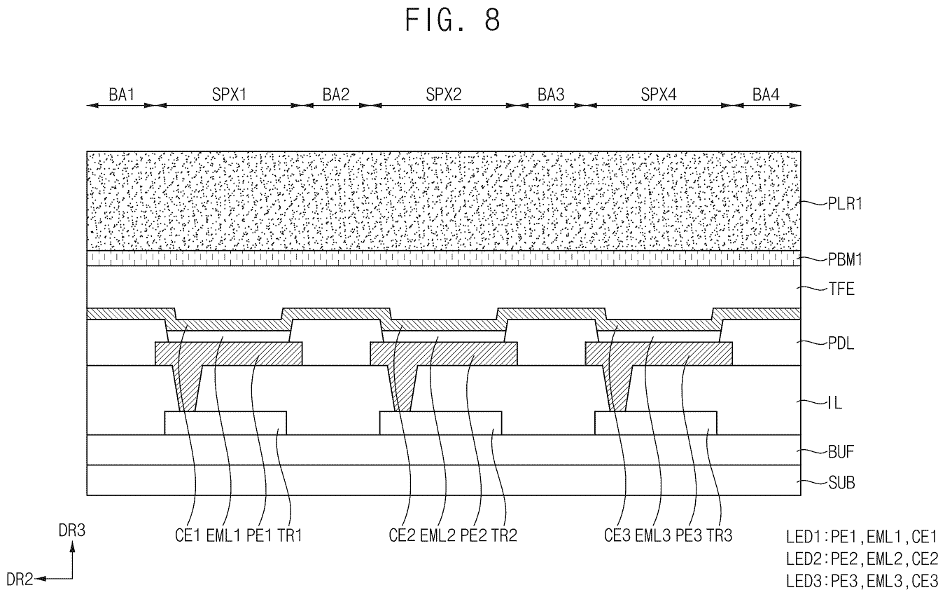

Referring to FIG. 8, a first preliminary refractive layer PLR1 may be formed on the first preliminary black matrix layer PBM1. For example, a thickness of the first preliminary refractive layer PLR1 in the third direction DR3 may be about 10 micrometers. However, this value is an example, and the thickness of the first preliminary refractive layer PLR1 may be appropriately changed.

In an embodiment, the first preliminary refractive layer PLR1 may include an organic material. For example, the first preliminary refractive layer PLR1 may include an acrylic resin, a polyacrylic resin, a polyimide resin, an epoxy resin, a melanin resin, or the like. These materials may be used alone or in combination with each other. However, embodiments are not limited thereto, and the first preliminary refractive layer PLR1 may include other kinds of organic materials.

The first preliminary refractive layer PLR1 may have a first refractive index. In an embodiment, the first refractive index of the first preliminary refractive layer PLR1 may be equal to or greater than about 1.5 and equal to or less than about 1.55 or may be in a range of about 1.5 to about 1.55. For example, the first refractive index may be about 1.5. However, these values are examples, and the first refractive index may be appropriately changed.

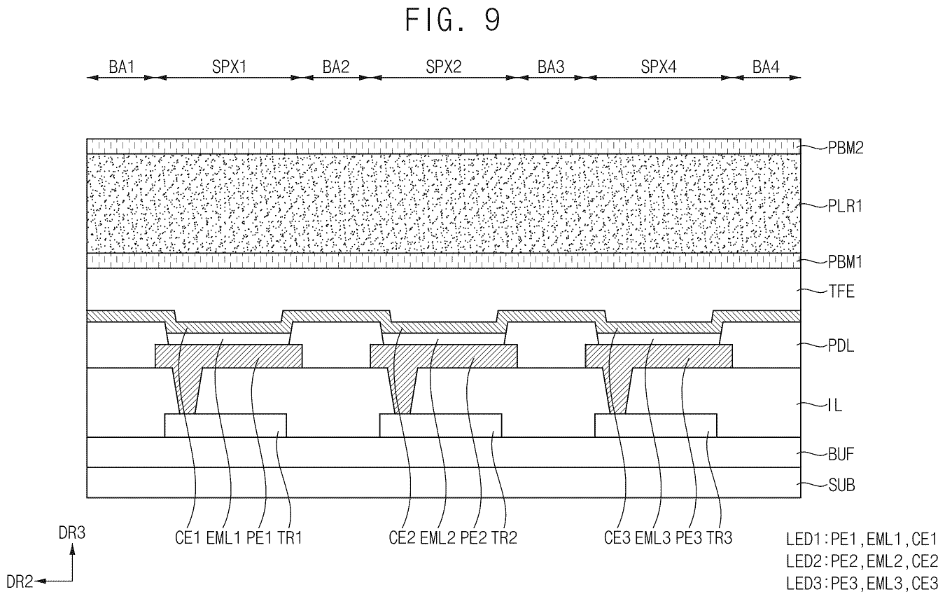

Referring to FIG. 9, a second preliminary black matrix layer PBM2 may be formed on the first preliminary refractive layer PLR1. In an embodiment, the second preliminary black matrix layer PBM2 may include an inorganic material. For example, the second preliminary black matrix layer PBM2 may include an inorganic material such as molybdenum-tantalum oxide (“MTO”). For example, the second preliminary black matrix layer PBM2 may have an MTO monolayer structure.

In another example, the second preliminary black matrix layer PBM2 may have a double layer structure including MTO/Mo, MTO/Cu, MTO/Al, or the like. These materials may be used alone or in combination with each other.

However, embodiments are not limited thereto, and the second preliminary black matrix layer PBM2 may include various materials having relatively low transmittance and reflectance and relatively high absorption. For example, the second preliminary black matrix layer PBM2 may include an organic material including a black pigment.

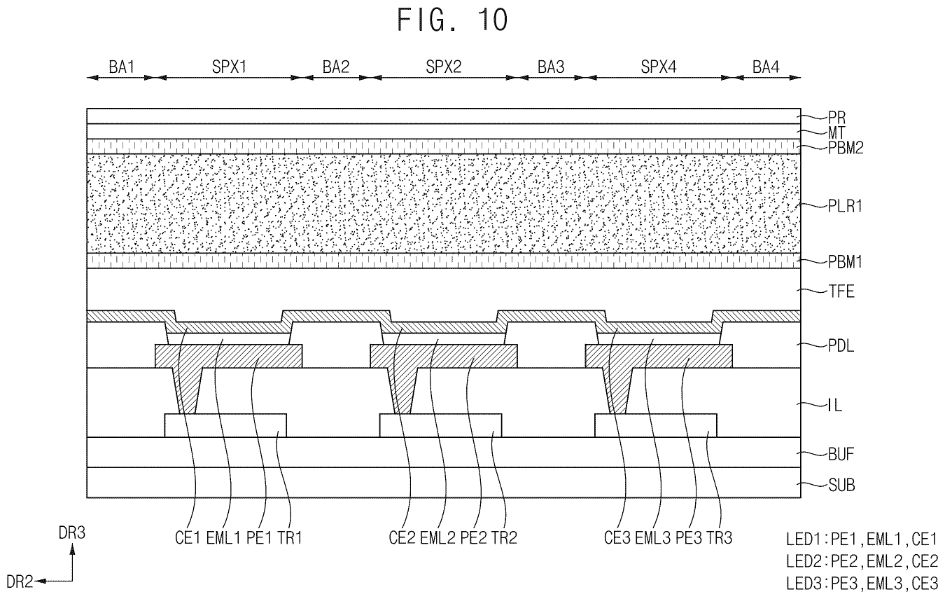

Referring to FIG. 10, a metal layer MT may be formed on the second preliminary black matrix layer PBM2. For example, the metal layer MT may include a metal material such as aluminum. A photoresist layer PR may be formed on the metal layer MT.

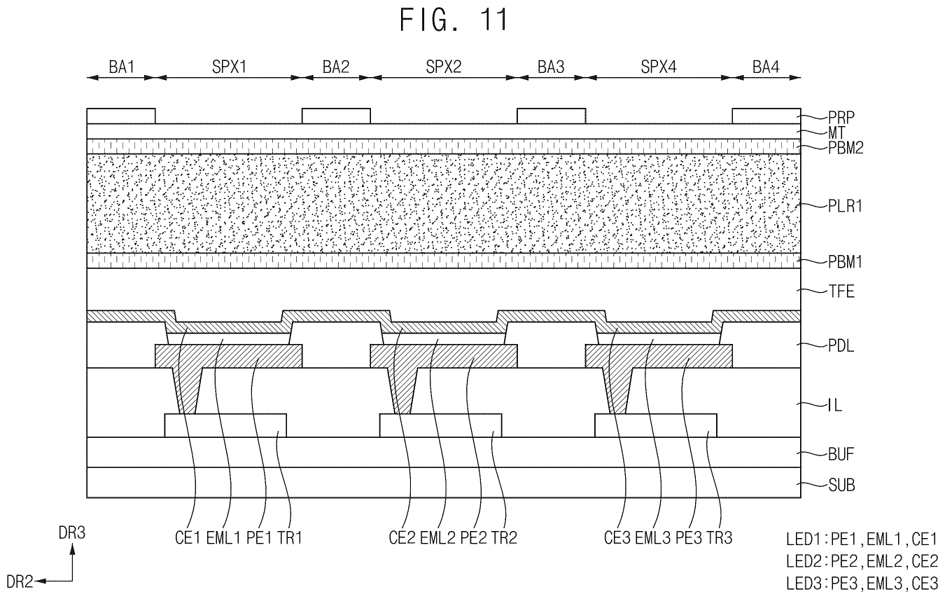

Referring to FIGS. 10 and 11, a mask including a transmitting area and a light-blocking area may be formed on the photoresist layer PR. In the transmitting area, light may transmit to the photoresist layer PR on the mask. Light may not transmit to the photoresist layer PR on the mask in the light-blocking area.

The photoresist layer PR may be a negative photoresist or a positive photoresist. For convenience of explanation, the photoresist layer PR will be described based on the case of a positive photoresist.

The transmitting area of the mask may overlap the first sub-pixel area SPX1, the second sub-pixel area SPX2, and the fourth sub-pixel area SPX4 in plan view. The light-blocking area of the mask may overlap the first non-light emitting area BA1, the second non-light emitting area BA2, the third non-light emitting area BA3, and the fourth non-light emitting area BA4 in plan view.

A portion of the photoresist layer PR overlapping the transmitting area may be dissolved after an exposure process and a development process. A portion of the photoresist layer PR overlapping the light-blocking area may not be dissolved even after the exposure process and the development process.

Accordingly, a portion of the photoresist layer PR overlapping the first sub-pixel area SPX1, the second sub-pixel area SPX2, and the fourth sub-pixel area SPX4 in plan view may be removed. Accordingly, a photoresist pattern layer PRP may be formed.

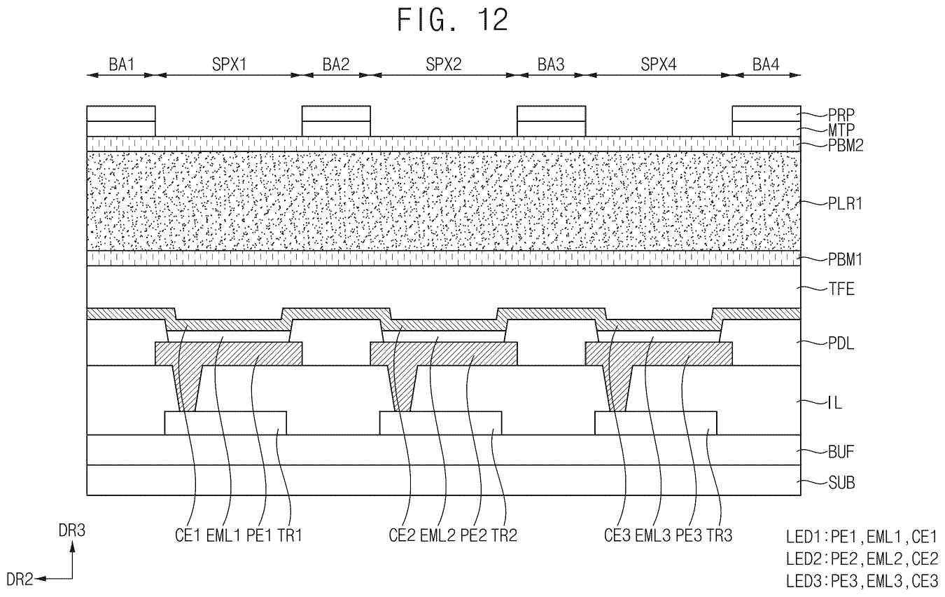

Referring to FIGS. 11 and 12, a portion of the metal layer MT overlapping the first sub-pixel area SPX1, the second sub-pixel area SPX2, and the fourth sub-pixel area SPX4 in plan view may be removed. For example, the portion of the metal layer MT overlapping the first sub-pixel area SPX1, the second sub-pixel area SPX2, and the fourth sub-pixel area SPX4 in plan view may be removed through an etching process. Accordingly, a metal pattern layer MTP may be formed.

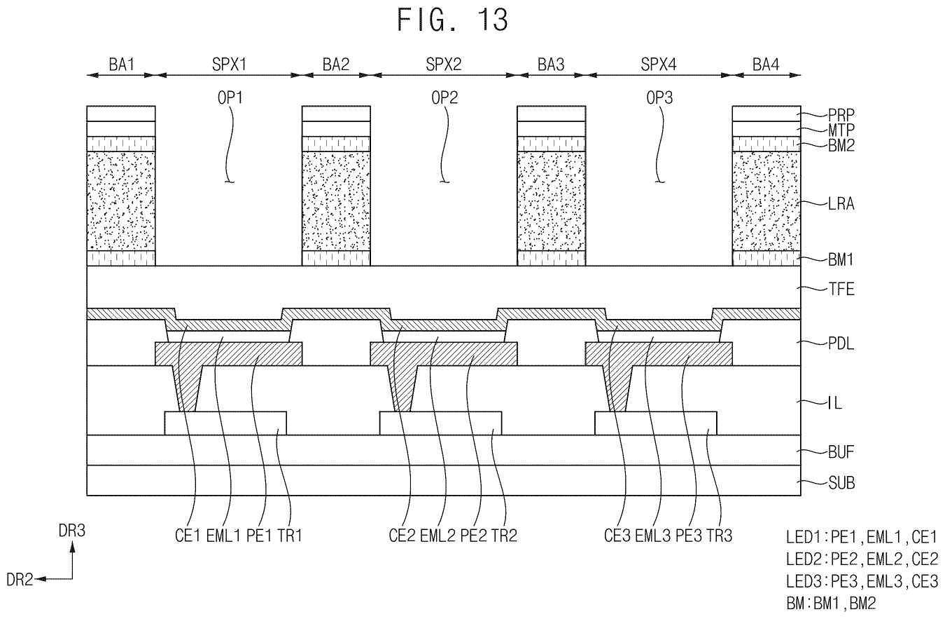

Referring to FIGS. 12 and 13, openings may be formed by removing portions of the first preliminary black matrix layer PBM1, the first preliminary refractive layer PLR1, and the second preliminary black matrix layer PBM2. For example, the portions of the first preliminary black matrix layer PBM1, the first preliminary refractive layer PLR1, and the second preliminary black matrix layer PBM2 may be removed by an etching process. For example, portions of the first preliminary black matrix layer PBM1, the first preliminary refractive layer PLR1, and the second preliminary black matrix layer PBM2 overlapping the first sub-pixel area SPX1 in plan view may be removed to form a first opening OP1. For example, portions of the first preliminary black matrix layer PBM1, the first preliminary refractive layer PLR1, and the second preliminary black matrix layer PBM2 overlapping the second sub-pixel area SPX2 in plan view may be removed to form a second opening OP2. For example, portions of the first preliminary black matrix layer PBM1, the first preliminary refractive layer PLR1, and the second preliminary black matrix layer PBM2 overlapping the fourth sub-pixel area SPX4 in plan view may be removed to form a third opening OP3. Accordingly, the first black matrix pattern layers BM1, first refractive pattern layers LRA, and the second black matrix pattern layers BM2 may be formed.

In an embodiment, the portions of the first preliminary black matrix layer PBM1, the first preliminary refractive layer PLR1, and the second preliminary black matrix layer PBM2 may be simultaneously removed. For example, the portions of the first preliminary black matrix layer PBM1, the first preliminary refractive layer PLR1, and the second preliminary black matrix layer PBM2 overlapping the first sub-pixel area SPX1 in plan view may be simultaneously removed to form the first opening OP1. For example, the portions of the first pr eliminary black matrix layer PBM1, the first preliminary refractive layer PLR1, and the second preliminary black matrix layer PBM2 overlapping the second sub-pixel area SPX2 in plan view may be simultaneously removed to form the second opening OP2. For example the portions of the first preliminary black matrix layer PBM1, the first preliminary refractive layer PLR1, and the second preliminary black matrix layer PBM2 overlapping the third sub-pixel area SPX3 in plan view may be simultaneously removed to form the third opening OP3. Accordingly, the first black matrix pattern layers BM1 and the second black matrix pattern layers BM2 may not be misaligned in plan view. For example, the first black matrix pattern layers BM1 and second black matrix pattern layers BM2 may be disposed in the first non-light emitting area BA1, the second non-light emitting area BA2, the third non-light emitting area BA3, and the fourth non-light emitting area BA4 without error.

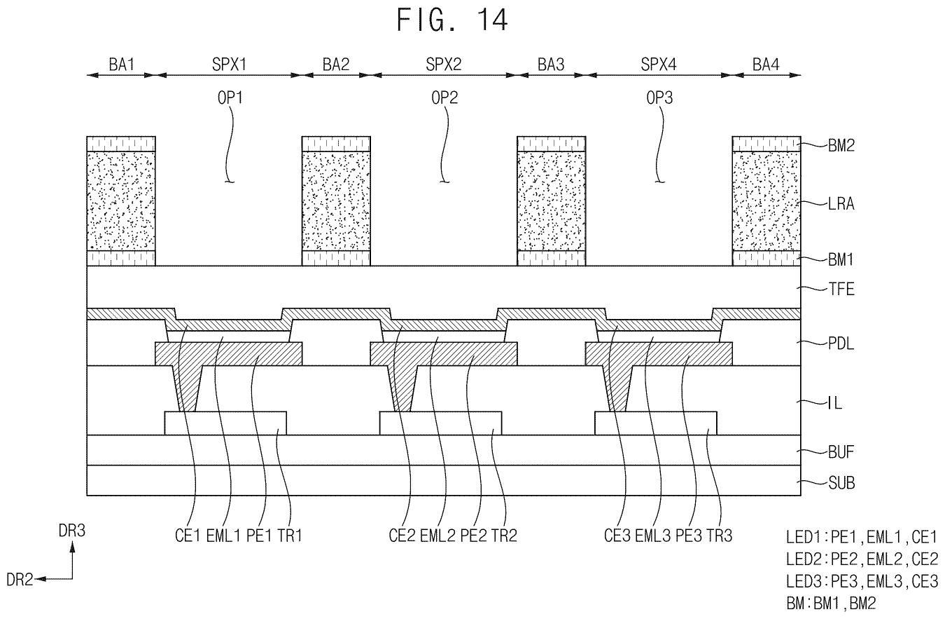

Referring to FIGS. 13 and 14, the photoresist pattern layer PRP and the metal pattern layer MTP may be removed.

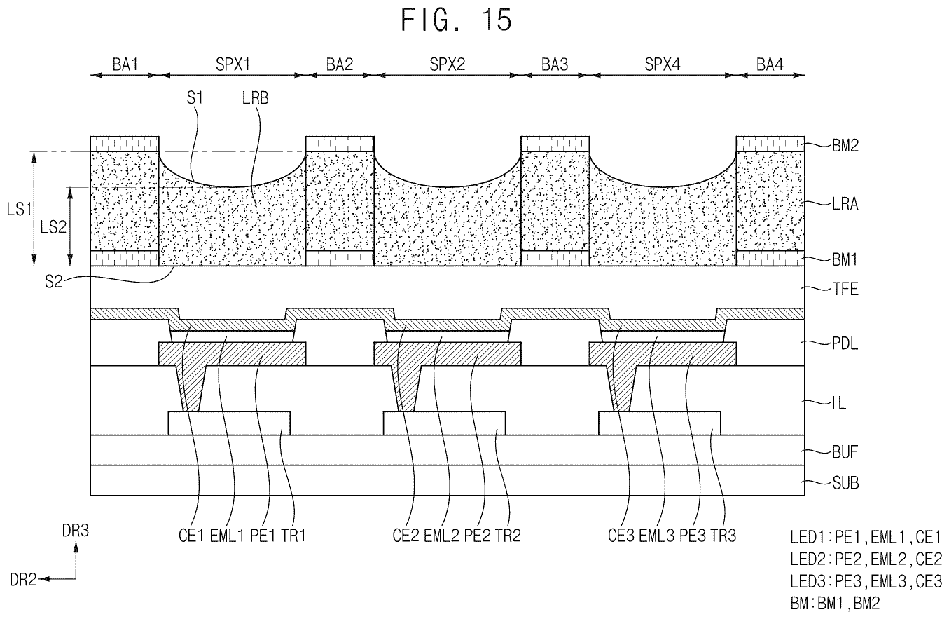

Referring to FIGS. 14 and 15, second refractive pattern layers LRB may be formed to fill the opening. For example, the second refractive pattern layers LRB may be formed to fill at least a portion of the first opening OP1, at least a portion of the second opening OP2, and at least a portion of the third opening OP3.

The second refractive pattern layers LRB may have an upper surface and a lower surface. For example, the second refractive pattern layers LRB may include an upper surface S1 and a lower surface S2 in the first sub-pixel area SPX1. The lower surface S2 of the second refractive pattern layers LRB may be a surface facing toward the first light emitting element LED1 in the first sub-pixel area SPX1. The upper surface S1 of the second refractive pattern layers LRB may be opposite to the lower surface S2.

In an embodiment, the upper surface S1 of the second refractive pattern layers LRB may be a convex surface. For example, the upper surface S1 of the second refractive pattern layers LRB may be a convex surface recessed toward the first light emitting element LED1 in the first sub-pixel area SPX1. For example, the upper surface S1 of the second refractive pattern layers LRB may be a downwardly convex surface.

The second refractive pattern layers LRB may have the upper surface S1 convex (or recessed) toward the first light emitting element LED1 due to surface tension with the first refractive pattern layers LRA. For example, the second refractive pattern layers LRB may have the upper surface S1 convex (or recessed) toward the first light emitting element LED1 without a separate etching process.

In an embodiment, a separation distance LS2 in the third direction DR3 between the encapsulation layer TFE and a portion of the upper surface S1 of the second refractive pattern layers LRB closest to the lower surface S2 may be smaller than a separation distance LS1 in the third direction DR3 between the encapsulation layer TFE and a plane extending from the lower surface of the second black matrix pattern layers BM2. For example, the upper surface S1 of the second refractive pattern layers LRB may be formed closer to the encapsulation layer TFE than the second black matrix pattern layers BM2. For example, the upper surface S1 of the second refractive pattern layers LRB may be formed below the second black matrix pattern layers BM2.

In an embodiment, the second refractive pattern layers LRB may include an organic material. For example, the second refractive pattern layers LRB may include an acrylic resin, a polyacrylic resin, a polyimide resin, an epoxy resin, a melanin resin, or the like. These materials may be used alone or in combination with each other. However, embodiments are not limited thereto, and the second refractive pattern layers LRB may include other types of organic materials.

The second refractive pattern layers LRB may have a second refractive index. In an embodiment, the second refractive index of the second refractive pattern layers LRB may be equal to or greater than about 1.5 and equal to or less than about 1.55 or may be in a range of about 1.5 to about 1.55. For example, the second refractive index may be about 1.5. However, these values are examples, and the second refractive index may be appropriately changed.

In an embodiment, the second refractive index of the second refractive pattern layers LRB and the first refractive index of the first refractive pattern layers LRA may be substantially the same. For example, each of the second refractive index of the second refractive pattern layers LRB and the first refractive index of the first refractive pattern layers LRA may be about 1.5.

However, embodiments are not limited thereto, and in another embodiment, the second refractive index of the second refractive pattern layers LRB and the first refractive index of the first refractive pattern layers LRA may be different from each other. For example, the second refractive index of the second refractive pattern layers LRB may be about 1.55, and the first refractive index of the first refractive pattern layers LRA may be about 1.5.

In an embodiment, the second refractive pattern layers LRB and the first refractive pattern layers LRA may include substantially the same material. For example, the second refractive pattern layers LRB and the first preliminary refractive layer (e.g., the first preliminary refractive layer PLR1 of FIG. 8) mya include substantially the same material.

However, embodiments are not limited thereto, and the second refractive pattern layers LRB and the first refractive pattern layers LRA may include different materials. For example, the second refractive pattern layers LRB and the first preliminary refractive layer may include different materials.

The first refractive pattern layers LRA and the second refractive pattern layers LRB may constitute the first refractive layer LR1 of FIG. 3.

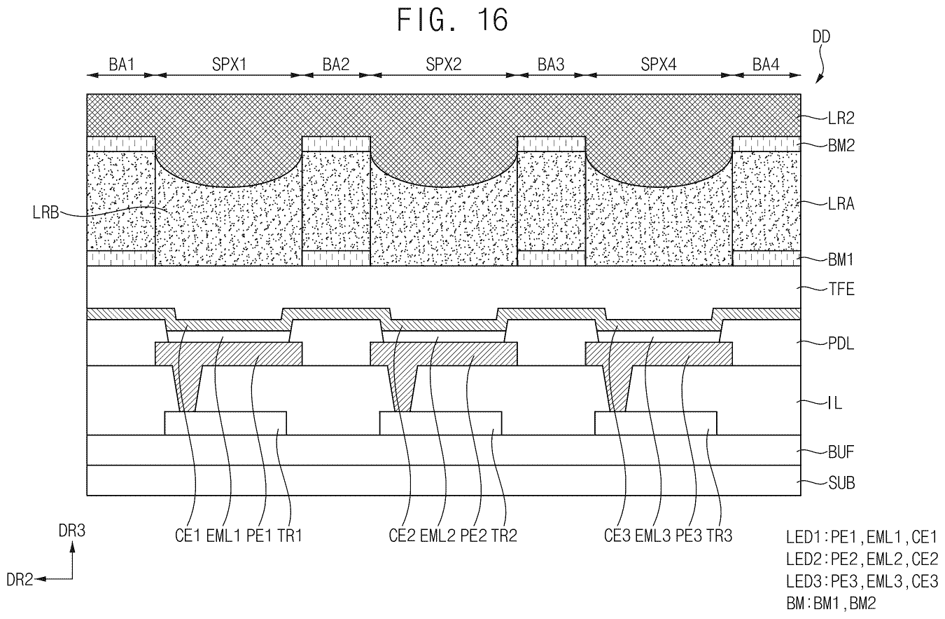

Referring to FIG. 16, the second refractive layer LR2 may be formed on the second refractive pattern layers LRB and the second black matrix pattern layers BM2. The second refractive layer LR2 may be formed to cover the second black matrix pattern layers BM2. For example, the second refractive layer LR2 may be formed to cover the second refractive pattern layers LRB. For example, the second refractive layer LR2 may be formed to cover the upper surface S1 of the second refractive pattern layers LRB.

In an embodiment, the second refractive layer LR2 may include an organic material. For example, the second refractive layer LR2 may include a polysiloxane-based, a polyacrylic-based resin, a polyimide-based resin, an epoxy resin, an acrylic resin, or the like. These materials may be used alone or in combination with each other. However, embodiments are not limited thereto, and the second refractive layer LR2 may include other types of organic materials.

In an embodiment, the second refractive layer LR2 may further include high refractive particles. The high refractive particles may be dispersed in the second refractive layer LR2 to increase a refractive index of the second refractive layer LR2. For example, the high refractive particles may include titanium dioxide, zirconium dioxide, zinc oxide, or the like. These materials may be used alone or in combination with each other.

The second refractive layer LR2 may have a third refractive index. In an embodiment, the third refractive index of the second refractive layer LR2 may be equal to or greater than about 1.6 and equal to or less than about 1.7 or may be in a range of about 1.6 to about 1.7. For example, the third refractive index may be about 1.6. However, these values are examples, and the third refractive index may be appropriately changed. For example, the third refractive index of the second refractive layer LR2 may be greater than the second refractive index of the second refractive pattern layers LRB. For example, the third refractive index of the second refractive layer LR2 may be greater than the first refractive index of the first refractive pattern layers LRA.

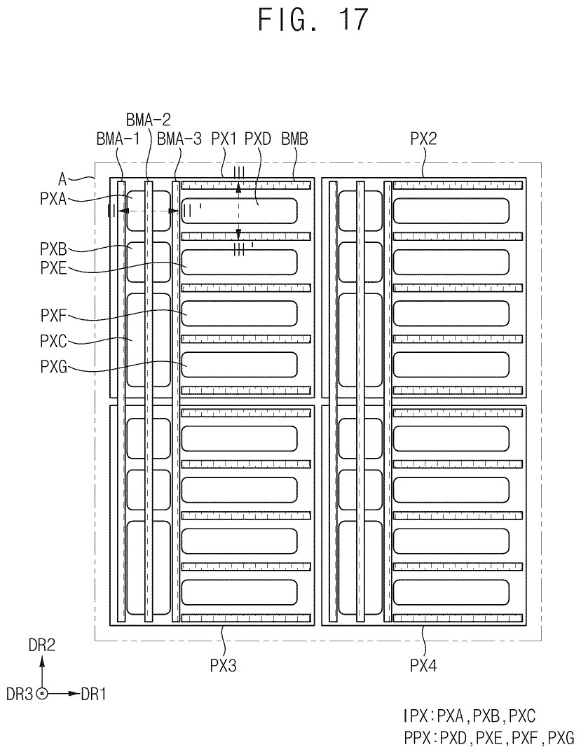

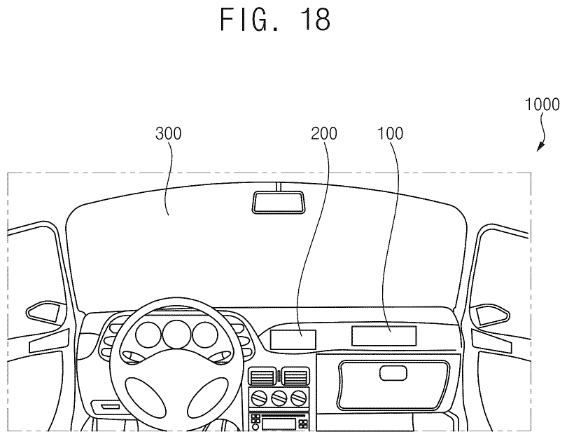

FIG. 17 is a plan view illustrating another example of an area A of FIG. 1. FIG. 18 is a diagram illustrating an interior of a vehicle to which the display device of FIG. 17 is applied.

Referring to FIG. 17, the first pixel area PX1 may include a first pixel area group IPX and a second pixel area group PPX. The first pixel area group IPX may include a (1-1)th sub-pixel area PXA, a (1-2)th sub-pixel area PXB, and a (1-3)th sub-pixel area PXC. The second pixel area group PPX may include a (2-1)th sub-pixel area PXD, a (2-2)th sub-pixel area PXE, a (2-3)th sub-pixel area PXF, and a (2-4)th sub-pixel area PXG.

The (1-1)th sub-pixel area PXA may emit first light, the (1-2)th sub-pixel area PXB may emit second light, and the (1-3)th sub-pixel area PXC may emit third light. For example, the first light may be red light, the second light may be green light, and the third light may be blue light. However, embodiments are not limited thereto. For example, the first light may be green light, the second light may be red light, and the third light may be blue light. As each of the (1-1)th sub-pixel area PXA, the (1-2)th sub-pixel area PXB, and the (1-3)th sub-pixel area PXC emits light, the first pixel area group IPX may emit light of a specific wavelength.

The (2-1)th sub-pixel area PXD may emit the first light, the (2-2)th sub-pixel area PXE may emit the second light, and each of the (2-3)th sub-pixel area PXF and the (2-4)th sub-pixel area PXG may emit the third light. As each of the (2-1)th sub-pixel area PXD, the (2-2)th sub-pixel area PXE, the (2-3)th sub-pixel area PXF, and the (2-4)th sub-pixel area PXG emits light, the second pixel area group PPX may emit light of a specific wavelength. For example, the second pixel area group PPX may emit light having substantially the same wavelength as the first pixel area group IPX. However, embodiments are not limited thereto, and the second pixel area group PPX may emit light having a different wavelength from the first pixel area group IPX.

The (1-2)th sub-pixel area PXB may be adjacent to the (1-1)th sub-pixel area PXA in a direction opposite to the second direction DR2 in plan view. The (1-3)th sub-pixel area PXC may be adjacent to the (1-2)th sub-pixel area PXB in the direction opposite to the second direction DR2 in plan view.

The (2-1)th sub-pixel area PXD may be adjacent to the (1-1)th sub-pixel area PXA in the first direction DR1 in plan view. The (2-2)th sub-pixel area PXE may be adjacent to the (1-2)th sub-pixel area PXB in the first direction DR1 in plan view. Each of the (2-3)th sub-pixel area PXF and the (2-4)th sub-pixel area PXG may be adjacent to the (1-3)th sub-pixel area PXC in the first direction DR1 in plan view.

The (2-2)th sub-pixel area PXE may be adjacent to the (2-1)th sub-pixel area PXD in the direction opposite to the second direction DR2 in plan view. The (2-3)th sub-pixel area PXF may be adjacent to the (2-2)th sub-pixel area PXE in the direction opposite to the second direction DR2 in plan view. The (2-4)th sub-pixel area PXG may be adjacent to the (2-3)th sub-pixel area PXF in the direction opposite to the second direction DR2 in plan view.

The display device (e.g., the display device DD of FIG. 1) may further include a first black matrix pattern layer BMA-1, a second black matrix pattern layer BMA-2, a third black matrix pattern layer BMA-3, and fourth black matrix pattern layers BMB.

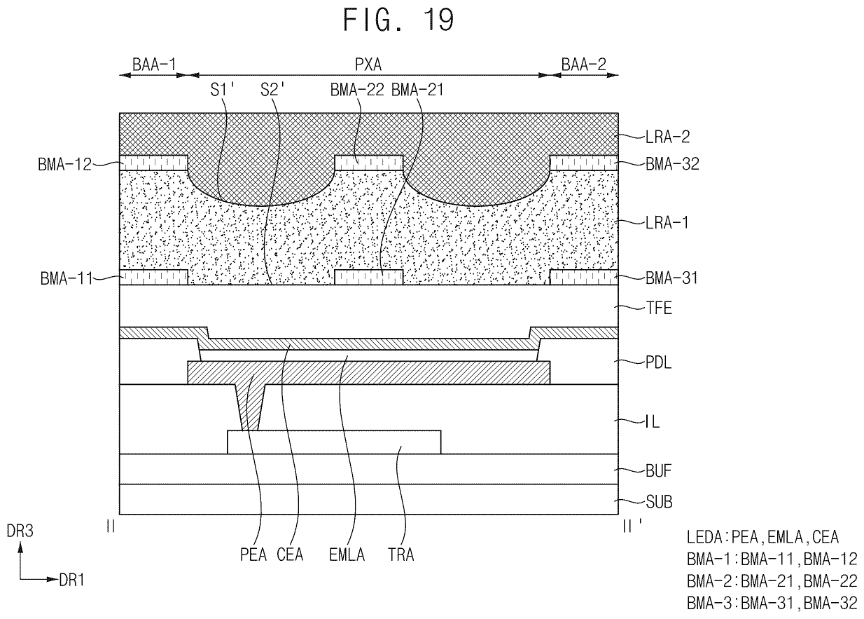

The first black matrix pattern layer BMA-1 may be adjacent to the (1-1)th sub-pixel area PXA in a direction opposite to the first direction DR1 in plan view. For example, the first black matrix pattern layer BMA-1 may be disposed in a (1-1)th non-light emitting area (for example, a (1-1)th non-light emitting area BAA-1 of FIG. 19). The first black matrix pattern layer BMA-1 may extend in the second direction DR2.

The second black matrix pattern layer BMA-2 may cross the (1-1)th sub-pixel area PXA, the (1-2)th sub-pixel area PXB, and the (1-3)th sub-pixel area PXC in plan view. For example, the second black matrix pattern layer BMA-2 may cross a central portion of the (1-1)th sub-pixel area PXA, a central portion of the (1-2)th sub-pixel area PXB, and a central portion of the (1-3)th sub-pixel area PXC in plan view. The second black matrix pattern layer BMA-2 may extend in the second direction DR2. For example, the second black matrix pattern layer BMA-2 may be parallel to the first black matrix pattern layer BMA-1.

The third black matrix pattern layer BMA-3 may be adjacent to the (1-1)th sub-pixel area PXA in the first direction DR1 in plan view. For example, the third black matrix pattern layer BMA-3 may be disposed in a (1-2)th non-light emitting area (for example, a (1-2)th non-light emitting area BAA-2 of FIG. 19).

For example, the third black matrix pattern layer BMA-3 may be disposed between the (1-1)th sub-pixel area PXA and the (2-1)th sub-pixel area PXD. The third black matrix pattern layer BMA-3 may extend in the second direction DR2. For example, the third black matrix pattern layer BMA-3 may be parallel to the first black matrix pattern layer BMA-1 and the second black matrix pattern layer BMA-2.

The fourth black matrix pattern layers BMB may be disposed in a non-light emitting area adjacent to the (2-1)th sub-pixel area PXD, the (2-2)th sub-pixel area PXE, the (2-3)th sub-pixel area PXF, and the (2-4)th sub-pixel area PXG. For example, the fourth black matrix pattern layers BMB may overlap the non-light emitting area adjacent to the (2-1)th sub-pixel area PXD, the (2-2)th sub-pixel area PXE, the (2-3)th sub-pixel area PXF, and the (2-4)th sub-pixel area PXG in plan view.

For example, the fourth black matrix pattern layers BMB may be disposed in a (2-1)th non-light emitting area (e.g., a (2-1)th non-light emitting area BAB-1 of FIG. 19) and a (2-2)th non-light emitting area (e.g., a (2-2)th non-light emitting area BAB-2 of FIG. 19) adjacent to the (2-1)th sub-pixel area PXD. The fourth black matrix pattern layers BMB may extend in the first direction DR1.

In an embodiment, the fourth black matrix pattern layers BMB may be separated from the third black matrix pattern layer BMA-3. For example, an end portion of the fourth black matrix pattern layers BMB may be separated from the third black matrix pattern layer BMA-3.

However, embodiments are not limited thereto, and in another embodiment, the fourth black matrix pattern layers BMB may be connected to the third black matrix pattern layer BMA-3. For example, the end portion of the fourth black matrix pattern layers BMB may be connected to the third black matrix pattern layer BMA-3.

The second pixel area PX2, the third pixel area PX3, and the fourth pixel area PX4 may have substantially the same structure as the first pixel area PX1.

Referring further to FIG. 18, a vehicle 1000 may refer to various devices for moving an object such as a human or an object from a departure point to a destination. For example, the vehicle 1000 may include a four-wheeled vehicle, a three-wheeled vehicle, a motor device, a train, or the like.

The vehicle 1000 may include a passenger dashboard 100, a center fascia 200, and a window 300. For example, the passenger dashboard 100 and the center fascia 200 may be installed inside the vehicle 1000. For example, the window 300 may be installed in front of the vehicle 1000. The passenger dashboard 100 may be disposed corresponding to a passenger seat. The center fascia 200 may be disposed at one side of the passenger dashboard 100.

In an embodiment, the display device of FIG. 17 may be included in the passenger dashboard 100. In the privacy mode, an image emitted from the display device included in the passenger dashboard 100 may not be viewed in a driver's seat. In of the privacy mode, the image emitted from the display device included in the passenger dashboard 100 may be viewed in the passenger seat.

In the privacy mode, the first pixel area group IPX may emit light, and the second pixel area group PPX may not emit light. For example, in the privacy mode, each of the (1-1)th sub-pixel area PXA, the (1-2)th sub-pixel area PXB, and the (1-3)th sub-pixel area PXC may emit light of a specific wavelength, so that the first pixel area group IPX may emit light of a specific wavelength. Since the display device includes the first black matrix pattern layer BMA-1, the second black matrix pattern layer BMA-2, and the third black matrix pattern layer BMA-3, light emitted from the first pixel area group IPX may reach the passenger seat and may not reach the driver seat.

In the privacy mode, each of the (2-1)th sub-pixel area PXD, the (2-2)th sub-pixel area PXE, the (2-3)th sub-pixel area PXF, and the (2-4)th sub-pixel area PXG may not emit light.

In the public mode, an image emitted from the display device included in the passenger dashboard 100 may be viewed from the passenger seat and the driver seat.

In the public mode, each of the first pixel area group IPX and the second pixel area group PPX may emit light. For example, each of the (1-1)th sub-pixel area PXA, the (1-2)th sub-pixel area PXB, and the (1-3)th sub-pixel area PXC emits light, so that the first pixel area group IPX may emit light of a specific wavelength. For example, each of the (2-1)th sub-pixel area PXD, the (2-2)th sub-pixel area PXE, the (2-3)th sub-pixel area PXF, and the (2-4)th sub-pixel area PXG emits light, so that the second pixel area group PPX may emit light of a specific wavelength.

In the public mode, since the display device includes the first black matrix pattern layer BMA-1, the second black matrix pattern layer BMA-2, and the third black matrix pattern layer BMA-3, light emitted from the first pixel area group IPX may reach the passenger seat and may not reach the driver seat.

For example, light emitted from the second pixel area group PPX may reach the driver's seat. Since the display device includes the fourth black matrix pattern layers BMB, the display device may have a narrow viewing angle. For example,

The display device may have a narrow viewing angle in the second direction DR2 and a direction opposite to the second direction DR2. Accordingly, an image emitted from the display device may not proceed toward the window 300. Accordingly, the image emitted from the display device may not be reflected by the window 300 and may not reach the driver's seat.

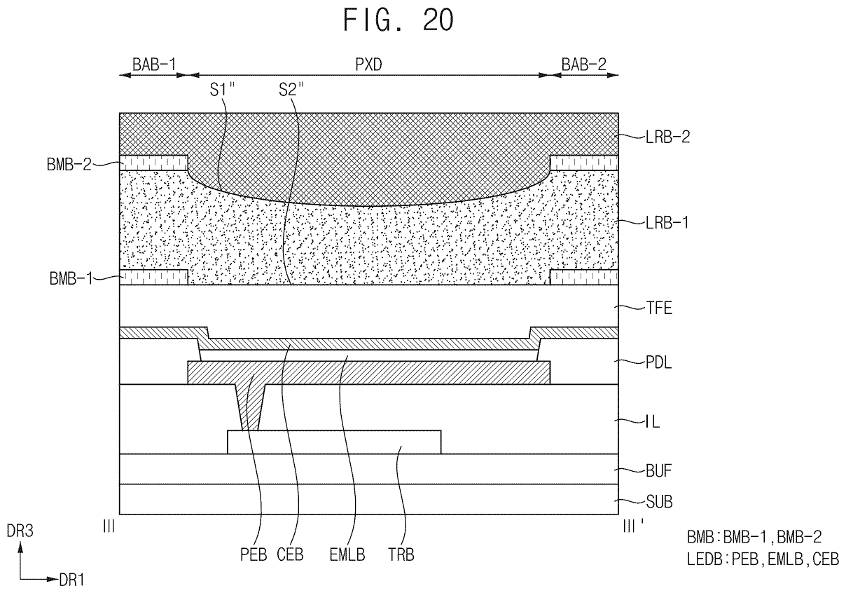

FIG. 19 is a schematic cross-sectional view of the display device of FIG. 18 taken along line II-II′. FIG. 20 is a schematic cross-sectional view of the display device of FIG. 18 taken along line III-III.

In describing the display device of FIGS. 19 and 20, substantially the same reference numerals are assigned to components that are substantially the same as those of the display device DD of FIG. 3, and a detailed description thereof may be omitted for descriptive convenience.

Referring to FIG. 19, a first light emitting element LEDA may be disposed in the (1-1)th sub-pixel area PXA. The first light emitting element LEDA may include a first pixel electrode PEA, a first light emitting layer EMLA, and a first common electrode CEA.

The first pixel electrode PEA may be connected to a first transistor TRA through a contact hole defining through the insulating layer IL.

The first black matrix pattern layer BMA-1 may include a (1-1)th black matrix pattern layer BMA-11 and a (1-2)th black matrix pattern layer BMA-12. The second black matrix pattern layer BMA-2 may include a (2-1)th black matrix pattern layer BMA-21 and a (2-2)th black matrix pattern layer BMA-22. The third black matrix pattern layer BMA-3 may include a (3-1)th black matrix pattern layer BMA-31 and a (3-2)th black matrix pattern layer BMA-32.

The (1-1)th black matrix pattern layer BMA-11 may be disposed on the first light emitting element LEDA. For example, the (1-1)th black matrix pattern layer BMA-11 may be disposed on the encapsulation layer TFE. The (1-1)th black matrix pattern layer BMA-11 may be disposed in a (1-1)th non-light emitting area BAA-1.

The (2-1)th black matrix pattern layer BMA-21 may be disposed on the first light emitting element LEDA. For example, the (2-1)th black matrix pattern layer BMA-21 may be disposed on the encapsulation layer TFE. The (2-1)th black matrix pattern layer BMA-21 may be spaced apart from the (1-1)th black matrix pattern layer BMA-11 in the first direction DR1. The (2-1)th black matrix pattern layer BMA-21 may be disposed in at least a portion of the (1-1)th sub-pixel area PXA. For example, the (2-1)th black matrix pattern layer BMA-21 may be disposed in a central portion of the (1-1)th sub-pixel area PXA. For example, the (2-1)th black matrix pattern layer BMA-21 may be disposed between the (1-1)th black matrix pattern layer BMA-11 and the (3-1)th black matrix pattern layer BMA-31.

The (3-1)th black matrix pattern layer BMA-31 may be disposed on the first light emitting element LEDA. For example, the (3-1)th black matrix pattern layer BMA-31 may be disposed on the encapsulation layer TFE. The (3-1)th black matrix pattern layer BMA-31 may be disposed in a (1-2)th non-light emitting area BAA-2.

Each of the (1-1)th black matrix pattern layer BMA-11, the (2-1)th black matrix pattern layer BMA-21, and the (3-1)th black matrix pattern layer BMA-31 may include an inorganic material. For example, each of the (1-1)th black matrix pattern layer BMA-11, the (2-1)th black matrix pattern layer BMA-21, and the (3-1)th black matrix pattern layer BMA-31 may include an inorganic material such as molybdenum-tantalum oxide (“MTO”). For example, each of the (1-1)th black matrix pattern layer BMA-11, the (2-1)th black matrix pattern layer BMA-21, and the (3-1)th black matrix pattern layer BMA-31 may have an MTO monolayer structure.

In another example, each of the (1-1)th black matrix pattern layer BMA-11, the (2-1)th black matrix pattern layer BMA-21, and the (3-1)th black matrix pattern layer BMA-31 may have a double layer structure including MTO/Mo, MTO/Cu, MTO/Al, or the like. These materials may be used alone or in combination with each other.

However, embodiments are not limited thereto, and each of the (1-1)th black matrix pattern layer BMA-11, the (2-1)th black matrix pattern layer BMA-21, and the (3-1)th black matrix pattern layer BMA-31 may include various materials having relatively low transmittance and reflectance and relatively high absorption. For example, each of the (1-1)th black matrix pattern layer BMA-11, the (2-1)th black matrix pattern layer BMA-21, and the (3-1)th black matrix pattern layer BMA-31 may include an organic material including a black pigment.

A (1-1)th refractive layer LRA-1 may be disposed on the encapsulation layer TFE. The (1-1)th refractive layer LRA-1 may cover the (1-1)th black matrix pattern layer BMA-11, the (2-1)th black matrix pattern layer BMA-21, and the (3-1)th black matrix pattern layer BMA-31.

The (1-1)th refractive layer LRA-1 may include an upper surface S1′ and a lower surface S2′. The lower surface S2′ of the (1-1)th refractive layer LRA-1 may be a surface facing the substrate SUB. For example, the lower surface S2′ of the (1-1)th refractive layer LRA-1 may be a surface facing the first light emitting element LEDA. The upper surface S1′ of the (1-1)th refractive layer LRA-1 may be a surface opposite to the lower surface S2′. The upper surface S1′ of the (1-1)th refractive layer LRA-1 may be a boundary surface at which a (1-2)th refractive layer LRA-2, which will be described later, and the (1-1)th refractive layer LRA-1 are in contact with each other.

In an embodiment, the upper surface S1′ of the (1-1)th refractive layer LRA-1 may be a convex surface. For example, the upper surface S1′ of the (1-1)th refractive layer LRA-1 may be a convex surface recessed toward the first light emitting element LEDA. For example, the upper surface S1′ of the (1-1)th refractive layer LRA-1 may be a downwardly convex surface.

For example, the (1-1)th refractive layer LRA-1 may have a downwardly convex upper surface S1′ between the (1-2)th black matrix pattern layer BMA-12 and the (2-2)th black matrix pattern layer BMA-22. For example, the (1-1)th refractive layer LRA-1 may have a downwardly convex upper surface S1′ between the (2-2)th black matrix pattern layer BMA-22 and the (3-2)th black matrix pattern layer BMA-32.

In an embodiment, the (1-1)th refractive layer LRA-1 may include an organic material. For example, the (1-1)th refractive layer LRA-1 may include an acrylic resin, a polyacrylic resin, a polyimide resin, an epoxy resin, a melanin resin, or the like. These materials may be used alone or in combination with each other. However, embodiments are not limited thereto, and the (1-1)th refractive layer LRA-1 may include other kinds of organic materials.

The (1-1)th refractive layer LRA-1 may have a first refractive index. In an embodiment, the first refractive index of the (1-1)th refractive layer LRA-1 may be equal to or greater than about 1.5 and equal to or less than about 1.55 or may be in a range of about 1.5 to about 1.55. For example, the first refractive index may be about 1.5. However, these values are examples, and the first refractive index may be appropriately changed.

The (1-2)th black matrix pattern layer BMA-12 may be disposed on the (1-1)th refractive layer LRA-1. The (1-2)th black matrix pattern layer BMA-12 may be disposed in the (1-1)th non-light emitting area BAA-1. For example, the (1-2)th black matrix pattern layer BMA-12 may overlap the (1-1)th black matrix pattern layer BMA-11 in plan view.

The (2-2)th black matrix pattern layer BMA-22 may be disposed on the (1-1)th refractive layer LRA-1. The (2-2)th black matrix pattern layer BMA-22 may overlap the (2-1)th black matrix pattern layer BMA-21 in plan view.

The (3-2)th black matrix pattern layer BMA-32 may be disposed on the (1-1)th refractive layer LRA-1. The (3-2)th black matrix pattern layer BMA-32 may be disposed in the (1-2)th non-light emitting area BAA-2. For example, the (3-2)th black matrix pattern layer BMA-32 may overlap the (3-1)th black matrix pattern layer BMA-31 in plan view.

Each of the (1-2)th black matrix pattern layer BMA-12, the (2-2)th black matrix pattern layer BMA-22, and the (3-2)th black matrix pattern layer BMA-32 may include an inorganic material. For example, each of the (1-2)th black matrix pattern layer BMA-12, the (2-2)th black matrix pattern layer BMA-22, and the (3-2)th black matrix pattern layer BMA-32 may include an inorganic material such as molybdenum-tantalum oxide (“MTO”). For example, each of the (1-2)th black matrix pattern layer BMA-12, the (2-2)th black matrix pattern layer BMA-22, and the (3-2)th black matrix pattern layer BMA-32 may have an MTO monolayer structure.

In another example, each of the (1-2)th black matrix pattern layer BMA-12, the (2-2)th black matrix pattern layer BMA-22, and the (3-2)th black matrix pattern layer BMA-32 may have a double structure including MTO/Mo, MTO/Cu, MTO/Al, or the like. These materials may be used alone or in combination with each other.

However, embodiments are not limited thereto, and each of the (1-2)th black matrix pattern layer BMA-12, the (2-2)th black matrix pattern layer BMA-22, and the (3-2)th black matrix pattern layer BMA-32 may include various materials having relatively low transmittance and reflectance and relatively high absorption. For example, each of the (1-2)th black matrix pattern layer BMA-12, the (2-2)th black matrix pattern layer BMA-22, and the (3-2)th black matrix pattern layer BMA-32 may include an organic material including a black pigment.

A (1-2)th refractive layer LRA-2 may be disposed on the (1-1)th refractive layer LRA-1, the (1-2)th black matrix pattern layer BMA-12, the (2-2)th black matrix pattern layer BMA-22, and the (3-2)th black matrix pattern layer BMA-32. The (1-2)th refractive layer LRA-2 may cover the (1-2)th black matrix pattern layer BMA-12, the (2-2)th black matrix pattern layer BMA-22, and the (3-2)th black matrix pattern layer BMA-32. For example, the (1-2)th refractive layer LRA-2 may cover the (1-1)th refractive layer LRA-1. For example, the (1-2)th refractive layer LRA-2 may cover the upper surface S1′ of the (1-1)th refractive layer LRA-1.

In an embodiment, the (1-2)th refractive layer LRA-2 may include an organic material. For example, the (1-2)th refractive layer LRA-2 may include a polysiloxane-based, a polyacrylic-based resin, a polyimide-based resin, an epoxy resin, an acrylic resin, or the like.

These materials may be used alone or in combination with each other. However, embodiments are not limited thereto, and the (1-2)th refractive layer LRA-2 may include other kinds of organic materials.

In an embodiment, the (1-2)th refractive layer LRA-2 may further include high refractive particles. The high refractive particles may be dispersed in the (1-2)th refractive layer LRA-2 to increase a refractive index of the (1-2)th refractive layer LRA-2. For example, the high refractive particles may include titanium dioxide, zirconium dioxide, zinc oxide, or the like. These materials may be used alone or in combination with each other.

The (1-2)th refractive layer LRA-2 may have a second refractive index. In an embodiment, the second refractive index of the (1-2)th refractive layer LRA-2 may be equal to or greater than about 1.6 and equal to or less than about 1.7 or may be in a range of about 1.6 to about 1.7. For example, the second refractive index may be about 1.6. However, these values are examples, and the second refractive index may be appropriately changed. For example, the second refractive index may be greater than the first refractive index.

Referring further to FIG. 20, a second light emitting element LEDB may be disposed in the (2-1)th sub-pixel area PXD. The second light emitting element LEDB may include a second pixel electrode PEB, a second light emitting layer EMLB, and a second common electrode CEB. The fourth black matrix pattern layers BMB may include (4-1)th black matrix pattern layers BMB-1 and (4-2)th black matrix pattern layers BMB-2.

The second pixel electrode PEB may be connected to the second transistor TRB through a contact hole defining through the insulating layer IL.

The (4-1)th black matrix pattern layers BMB-1 may be disposed on the second light emitting element LEDB. For example, the (4-1)th black matrix pattern layers BMB-1 may be disposed on the encapsulation layer TFE. The (4-1)th black matrix pattern layers BMB-1 may be disposed in a (2-1)th non-light emitting area BAB-1 and a (2-2)th non-light emitting area BAB-2.

For example, the (4-1)th black matrix pattern layers BMB-1, the (1-1)th black matrix pattern layer BMA-11, the (2-1)th black matrix pattern layer BMA-21, and the (3-1)th black matrix pattern layer BMA-31 may include substantially the same material.

A (2-1)th refractive layer LRB-1 may be disposed on the encapsulation layer TFE. The (2-1)th refractive layer LRB-1 may cover the (4-1)th black matrix pattern layers BMB-1. The (2-1)th refractive layer LRB-1 may include an upper surface S1″ and a lower surface S2″. The lower surface S2″ of the (2-1)th refractive layer LRB-1 may be a surface facing the substrate SUB. For example, the lower surface S2″ of the (2-1)th refractive layer LRB-1 may be a surface facing the second light emitting element LEDB. The upper surface S1″ of the (2-1)th refractive layer LRB-1 may be a surface opposite to the lower surface S2″. The upper surface S1″ of the (2-1)th refractive layer LRB-1 may be a boundary surface at which a (2-2)th refractive layer LRB-2, which will be described later, and the (2-1)th refractive layer LRB-1 are in contact with each other.

In an embodiment, the upper surface S1″ of the (2-1)th refractive layer LRB-1 may be a convex surface. For example, the upper surface S1″ of the (2-1)th refractive layer LRB-1 may be a convex surface recessed toward the second light emitting element LEDB. For example, the upper surface S1″ of the (2-1)th refractive layer LRB-1 may be a downwardly convex surface. For example, the (2-1)th refractive layer LRB-1 may have a convex upper surface S1″ in the (2-1)th sub-pixel area PXD.

In an embodiment, the (2-1)th refractive layer LRB-1 and the (1-1)th refractive layer LRA-1 may include substantially the same material. For example, the (2-1)th refractive layer LRB-1 and the (1-1)th refractive layer LRA-1 may have substantially the same refractive index. For example, the (2-1)th refractive layer LRB-1 may have the first refractive index.

The (4-2)th black matrix pattern layers BMB-2 may be disposed on the (2-1)th refractive layer LRB-1. The (4-2)th black matrix pattern layers BMB-2 may be disposed in the (2-1)th non-light emitting area BAB-1 and the (2-2)th non-light emitting area BAB-2. For example, the (4-2)th black matrix pattern layers BMB-2 may overlap the (4-1)th black matrix pattern layers BMB-1 in plan view.

The (4-2)th black matrix pattern layers BMB-2, the (1-2)th black matrix pattern layer BMA-12, the (2-2)th black matrix pattern layer BMA-22, and the (3-2)th black matrix pattern layer BMA-32 may include substantially the same material.

A (2-2)th refractive layer LRB-2 may be disposed on the (2-1)th refractive layer LRB-1 and the (4-2)th black matrix pattern layers BMB-2. The (2-2)th refractive layer LRB-2 may cover the (4-2)th black matrix pattern layers BMB-2. For example, the (2-2)th refractive layer LRB-2 may cover the (2-1)th refractive layer LRB-1. For example, the (2-2)th refractive layer LRB-2 may cover the upper surface S1″ of the (2-1)th refractive layer LRB-1.

In an embodiment, the (2-2)th refractive layer LRB-2 and the (1-2)th refractive layer LRA-2 may include substantially the same material. For example, the (2-2)th refractive layer LRB-2 and the (1-2)th refractive layer LRA-2 may have substantially the same refractive index. For example, the (2-2)th refractive layer LRB-2 may have the second refractive index.

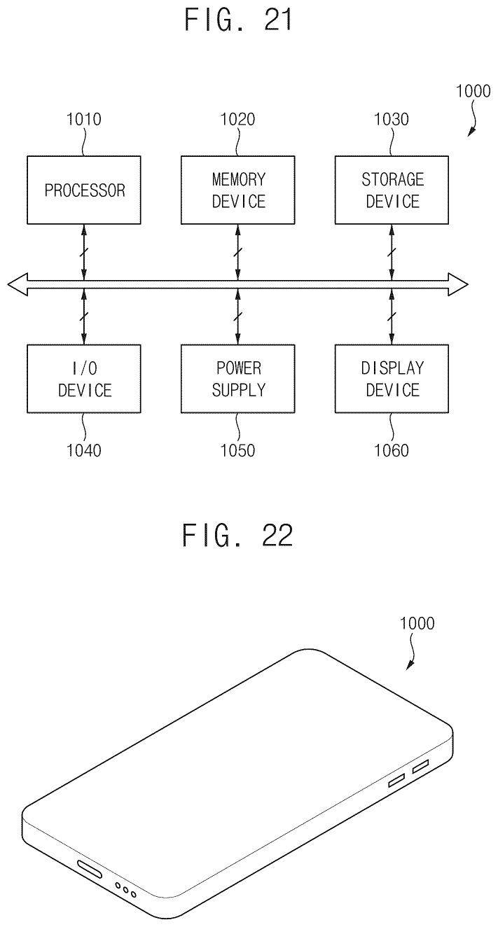

FIG. 21 is a block diagram illustrating an electronic device according to embodiments. FIG. 22 is a diagram illustrating an example in which the electronic device of FIG. 21 is implemented as a smart phone.

Referring to FIGS. 21 and 22, an electronic device 1000 may include a processor 1010, a memory device 1020, a storage device 1030, an input/output device 1040, a power supply 1050, and a display device 1060. In this case, the display device 1060 may be the display device DD of FIG. 1. In addition, the electronic device 1000 may further include several ports capable of communicating with a video card, a sound card, a memory card, a USB device, and/or the like.

According to an embodiment, as illustrated in the FIG. 22, the electronic device 1000 may be implemented as a smartphone. However, this is exemplary, and the electronic device 1000 may be implemented as various devices according to embodiments. For example, the electronic device 1000 may be implemented as a mobile phone, a video phone, a smart pad, a smart watch, a tablet PC, a vehicle navigation device, a computer monitor, a notebook computer, a head mounted display device, and/or the like.

The processor 1010 may be a microprocessor, a central processing unit, an application processor, and/or the like. The processor 1010 may be connected to other components through an address bus, a control bus, a data bus, and/or the like. In an embodiment, the processor 1010 may also be connected to an expansion bus such as a peripheral component interconnect (“PCI”) bus.

The memory device 1020 may store data necessary for operation of the electronic device 1000. For example, the memory device 1020 may include a nonvolatile memory device and/or a volatile memory device. Examples of the nonvolatile memory device may include erasable programmable read-only Memory (“EPROM”) device, electrically erasable programmable read-only memory (“EEPROM”) device, flash memory device, phase change random access memory (“PRAM”) device, resistance random access memory (“RRAM”) device, nano floating gate memory (“NFGM”) device, polymer random access memory (“PoRAM”) device, magnetic random access memory (“MRAM”) device, ferroelectric random access memory (“FRAM”) device, and/or the like. Examples of the volatile memory device may include dynamic random access memory (“DRAM”) device, static random access memory (“SRAM”) device, mobile DRAM device, and/or the like.

The storage device 1030 may include a solid state drive (“SSD”), a hard disk drive (“HDD”), a CD-ROM, and/or the like.

The input/output device 1040 may include an input mean such as a keyboard, a keypad, a touch pad, a touch screen, and a mouse, and/or the like, and an output mean such as a speaker and a printer. In an embodiment, the display device 1060 may be included in the input/output device 1040.

The power supply 1050 may supply power necessary for operation of the electronic device 1000. For example, the power supply 1050 may supply power necessary for operation of the display device 1060.

The display device 1060 may be connected to other components through buses or other communication links.

Embodiments may be applied to various display devices. For example, the present disclosure is applicable to various display devices such as display devices for vehicles, ships and aircraft, portable communication devices, display devices for exhibition or information transmission, medical display devices, and the like.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a light emitting element disposed in a pixel area;
first black matrix pattern layers disposed in a non-light emitting area adjacent to the pixel area;
a first refractive layer covering the first black matrix pattern layers and having a first refractive index, wherein
the first refractive layer includes a convex upper surface recessed toward the light emitting element; and
a second refractive layer covering the convex upper surface of the first refractive layer and having a second refractive index different from the first refractive index.

2. The display device of claim 1, wherein the second refractive index is greater than the first refractive index.

3. The display device of claim 2, wherein the first refractive index is in a range of about 1.5 to about 1.55, and the second refractive index is in a range of about 1.6 to about 1.7.

4. The display device of claim 1, wherein the first refractive layer includes the convex upper surface recessed toward the light emitting element in the pixel area.

5. The display device of claim 1, further comprising:
second black matrix pattern layers disposed on the first refractive layer in the non-light emitting area.

6. The display device of claim 5, wherein the second refractive layer covers the second black matrix pattern layers.

7. The display device of claim 1, wherein each of the first refractive layer and the second refractive layer includes an organic material.

8. The display device of claim 1, wherein
the first refractive layer includes a first portion disposed in the pixel area and a second portion disposed in the non-light emitting area, and
the first portion of the first refractive layer and the second portion of the first refractive layer include different materials.

9. A display device comprising:
a first light emitting element disposed in a (1-1)th sub-pixel area;
a second light emitting element disposed in a (2-1)th sub-pixel area adjacent to the (1-1)th sub-pixel area in a first direction in plan view;
a (1-1)th black matrix pattern layer adjacent to the (1-1)th sub-pixel area including the first light emitting element in a direction opposite to the first direction in plan view, and extending in a second direction intersecting the first direction;
a (2-1)th black matrix pattern layer disposed on the first light emitting element and extending in the second direction to cross the (1-1)th sub-pixel area in plan view;
(3-1)th black matrix pattern layers disposed in a non-light emitting area adjacent to the (2-1)th sub-pixel area including the second light emitting element and extending in the first direction;
a (1-1)th refractive layer disposed on the first light emitting element, covering the (1-1)th black matrix pattern layer and the (2-1)th black matrix pattern layer, having a first refractive index, the (1-1)th refractive layer including a convex upper surface recessed toward the first light emitting element; and
a (1-2)th refractive layer covering the convex upper surface of the (1-1)th refractive layer on the (1-1)th refractive layer and having a second refractive index different from the first refractive index.

10. The display device of claim 9, further comprising:
a (4-1)th black matrix pattern layer disposed between the (1-1)th sub-pixel area and the (2-1)th sub-pixel area, and extending in the second direction.

11. The display device of claim 10, wherein the (1-1)th refractive layer covers the (4-1)th black matrix pattern layer.

12. The display device of claim 11, further comprising:
a (1-2)th black matrix pattern layer disposed on the (1-1)th refractive layer and overlapping the (1-1)th black matrix pattern layer in plan view;
a (2-2)th black matrix pattern layer disposed on the (1-1)th refractive layer and overlapping the (2-1)th black matrix pattern layer in plan view; and
a (4-2)th black matrix pattern layer disposed on the (1-1)th refractive layer and overlapping the (4-1)th black matrix pattern layer in plan view.

13. The display device of claim 12, wherein the (1-2)th refractive layer covers the (1-2)th black matrix pattern layer, the (2-2)th black matrix pattern layer, and the (4-2)th black matrix pattern layer.

14. The display device of claim 12, wherein the (1-1)th refractive layer includes the convex upper surface recessed toward the first light emitting element between the (1-2)th black matrix pattern layer and the (2-2)th black matrix pattern layer.

15. The display device of claim 14, wherein the (1-1)th refractive layer includes the convex upper surface recessed toward the first light emitting element between the (2-2)th black matrix pattern layer and the (4-2)th black matrix pattern layer.

16. The display device of claim 9, further comprising:
a (2-1)th refractive layer covering the (3-1)th black matrix pattern layers, and having a convex upper surface recessed toward the second light emitting element.

17. The display device of claim 16, wherein the (2-1)th refractive layer has the first refractive index.

18. The display device of claim 17, further comprising:
a (2-2)th refractive layer covering the convex upper surface of the (2-1)th refractive layer on the (2-1)th refractive layer and having the second refractive index.

19. The display device of claim 18, wherein the second refractive index is greater than the first refractive index.

20. The display device of claim 19, wherein the first refractive index is in a range of about 1.5 to about 1.55, and the second refractive index is in a range of about 1.6 to about 1.7.

21. The display device of claim 18, further comprising:
(3-2)th black matrix pattern layers disposed on the (2-1)th refractive layer and overlapping the (3-1)th black matrix pattern layers in plan view, and
wherein the (2-2)th refractive layer covers the (3-2)th black matrix pattern layers.

22. A method of manufacturing a display device comprising:
forming a light emitting element in a pixel area;
forming a first preliminary black matrix layer to cover the light emitting element;
forming a first preliminary refractive layer on the first preliminary black matrix layer;
forming a second preliminary black matrix layer on the first preliminary refractive layer;
forming an opening by removing portions of the first preliminary black matrix layer, the first preliminary refractive layer, and the second preliminary black matrix layer;
forming first refractive pattern layers filling at least a portion of the opening, having a convex upper surface recessed toward the light emitting element, the first refractive pattern layers having a first refractive index; and
forming a second refractive layer covering the convex upper surface of the first refractive pattern layers and having a second refractive index different from the first refractive index.

23. The method of claim 22, wherein the second refractive index is greater than the first refractive index.

24. The method of claim 22, wherein the forming of the opening includes:
forming a metal layer and a photoresist layer on the second preliminary black matrix layer;
removing a portion of the metal layer and the photoresist layer overlapping the pixel area in plan view; and
removing portions of the first preliminary black matrix layer, the first preliminary refractive layer, and the second preliminary black matrix layer overlapping the pixel area in plan view.

25. The method of claim 22, wherein the first preliminary refractive layer and the first refractive pattern layers include a same material.

26. The method of claim 22, wherein each of first black matrix pattern layers, second refractive pattern layers, and second black matrix pattern layers is formed through the forming of the opening by removing the portions of the first preliminary black matrix layer, the first preliminary refractive layer, and the second preliminary black matrix layer.

27. The method of claim 26, wherein the convex upper surface of the first refractive pattern layers is formed below the second black matrix pattern layers.

28. An electronic device comprising:
a light emitting element disposed in a pixel area;
first black matrix pattern layers disposed in a non-light emitting area adjacent to the pixel area;
a first refractive layer covering the first black matrix pattern layers and having a first refractive index, wherein
the first refractive layer includes a convex upper surface recessed toward the light emitting element;
a second refractive layer covering the convex upper surface of the first refractive layer and having a second refractive index different from the first refractive index; and
a memory device configured to store data.
